(19) United States
(12) Patent Application Publication
(10) Pub. No.: US 2024/0219326 A1
(43) Pub. Date: Jul. 4, 2024

(54) SYSTEMS, APPARATUS, ARTICLES OF MANUFACTURE, AND METHODS TO INSPECT SEMICONDUCTOR WAFERS

(71) Applicant: Intel Corporation, Santa Clara, CA (US)

(72) Inventors: Oliver Patterson, San Jose, CA (US); Kale Beckwitt, Portland, OR (US)

(21) Appl. No.: 18/147,589

(22) Filed: Dec. 28, 2022

(51) Int. Cl. G01N 23/18; H01L 21/67

(52) U.S. Cl. CPC G01N 23/18; H01L 21/67288; G01N 2223/401; G01N 2223/418; G01N 2223/6116

(57) ABSTRACT

Systems, apparatus, articles of manufacture, and methods to inspect wafer manufacture are disclosed. An example apparatus includes processor circuitry to at least one of instantiate operations corresponding to the machine readable instructions or execute machine readable instructions to predict a structure of a semiconductor wafer that is to result from a second wafer manufacturing operation based on a first image of the semiconductor wafer obtained after a first wafer manufacturing operation, the second wafer manufacturing operation to be performed subsequent to the first wafer manufacturing operation, and determine whether an actual defect developed in the semiconductor wafer between completion of the first wafer manufacturing operation and completion of the second wafer manufacturing operation based on the predicted structure of the semiconductor wafer and a second image representative of the semiconductor wafer after completion of the second wafer manufacturing operation.

### FIELD OF THE DISCLOSURE

This disclosure relates generally to semiconductor wafers and, more particularly, to systems, apparatus, articles of manufacture, and methods to inspect semiconductor wafers.

### BACKGROUND

In recent years, sizes of integrated circuits have continued to reduce. Integrated circuits are produced on semiconductor wafers.

### BRIEF DESCRIPTION OF THE DRAWINGS

FIG. 1 is an illustration of an example system including an example wafer manufacturing system and an example wafer inspection system including wafer manufacturing analysis circuitry.

FIG. 2 is a block diagram of an example implementation of the example wafer manufacture analysis circuitry of FIG. 1.

FIG. 3A illustrates example manufactured word lines in a semiconductor wafer.

FIG. 3B illustrates a first prior art wafer inspection of the word lines of FIG. 3A.

FIG. 3C illustrates a second prior art wafer inspection of the word lines of FIG. 3A.

FIG. 4 illustrates an example wafer inspection performed by the example wafer manufacture analysis circuitry of FIGS. 1 and/or 2.

FIG. 5 is a flowchart representative of example machine readable instructions and/or example operations that may be executed and/or performed by example processor circuitry to implement the example wafer manufacture analysis circuitry of FIGS. 1 and/or 2.

FIG. 6 is another flowchart representative of example machine readable instructions and/or example operations that may be executed and/or performed by example processor circuitry to implement the example wafer manufacture analysis circuitry of FIGS. 1 and/or 2.

FIG. 7 is a block diagram of an example processing platform including processor circuitry structured to execute the example machine readable instructions and/or perform the example operations of FIGS. 5 and/or 6 to implement the example wafer manufacture analysis circuitry of FIGS. 1 and/or 2.

FIG. 8 is a block diagram of an example implementation of the processor circuitry of FIG. 7.

FIG. 9 is a block diagram of another example implementation of the processor circuitry of FIG. 7.

FIG. 10 is a block diagram of an example software distribution platform (e.g., one or more servers) to distribute software (e.g., software corresponding to the example machine readable instructions of FIGS. 5 and/or 6) to devices associated with semiconductor wafer manufacturers that perform wafer inspection.

In general, the same reference numbers will be used throughout the drawing(s) and accompanying written description to refer to the same or like parts. The figures are not substantially to scale.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmable with instructions to perform specific operations and including one or more semiconductor-based logic devices (e.g., electrical hardware implemented by one or more transistors). Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of processor circuitry is/are best suited to execute the computing task(s).

As used herein “threshold” is defined to be data such as a numerical value represented in any form, that may be used by processor circuitry as a reference for a comparison operation.

As used herein, data is defined to be information in any form that may be ingested, processed, interpreted and/or otherwise manipulated by processor circuitry to produce a result. The produced result may itself be data.

As used herein, a model is defined to be a set of instructions and/or data that may be ingested, processed, interpreted and/or otherwise manipulated by processor circuitry to produce a result. Often, a model is operated using input data to produce output data in accordance with one or more relationships reflected in the model. The model may be based on training data.

As used herein, a “defect” (also referred to herein as an “actual defect”) and areas or structures that are “defective” in a semiconductor wafer and/or chip are defined to be a difference between an obtained (e.g., manufactured) structure and a desired structure (e.g., a design) that impacts a functionality of the semiconductor. For example, the “defect” can negatively impact current flow in the semiconductor, such as by causing the current to flow through an unintended pathway (e.g., causing a short in the integrated circuit).

As used herein, a “nuisance defect” in a semiconductor wafer and/or chip is defined to be a difference between an obtained (e.g., manufactured) structure and a desired structure (e.g., a design) that does not impact a functionality of the semiconductor. For example, a “nuisance defect” can be a non-straight path of a word line (e.g., wiggle in the word line) that does not impact the functionality of the semiconductor.

### DETAILED DESCRIPTION

Integrated circuits have continued to decrease in critical dimensions with advances in manufacturing. However, such critical dimension reductions have made physical defects more difficult to detect. Specifically, respective positions and/or dimensions of structures, such as word lines, in the integrated circuits have encountered increased variation relative to the critical dimensions and minimum defect size as critical dimensions decrease. This increased variance in the respective positions and/or dimensions of structures has increased difficulties associated with differentiating nuisance defects from actual defects. Nuisance defects include structural anomalies that do not affect the operation of the corresponding circuitry. Actual defects, in contrast to nuisance defects, negatively impact one or more functions of the circuitry. Nuisance defects may be thought of as “false positives” of actual defects. Patterns of word lines in integrated circuits often encounter variability as a result of difficulties associated with maintaining a straight lengthwise span of the word lines during manufacturing. The word lines are positioned so close together that a deviation in the lengthwise span of a first word line can contact a second, adjacent word line resulting in an actual defect. However, in some instances, a lengthwise span of the second word line may alternatively exhibit deviation where the first word line avoids contact with the second word line. In such instances, the deviation in the lengthwise span of the word line may be flagged as an actual defect by known manufacturing tests, such as array mode, random mode, design mode, and/or the like, when in fact the deviation is a nuisance defect that does not impact the functionality of the integrated circuit. Nuisance defects have become increasingly difficult to differentiate from actual defects that impact the functionality of the integrated circuit. Misidentification of nuisance defects as actual defects reduces the yield of an associated semiconductor wafer thereby increasing costs and wasting resources, which potentially detrimentally affects the environment.

Semiconductor wafers sometimes go through the entire manufacturing process before electrical signal testing is able to reveal actual defects in the wafers. Completing manufacture of the defective circuitry wastes valuable time and resources. Detecting defects during the manufacturing sequence with in-line inspection can greatly reduce this waste. In-line inspection detects defects by comparing wafer images and looking for differences. When the difference in images is greater than a threshold, the inspection tool reports this occurrence as an actual defect. Because of the increase in pattern variation discussed above, greater numbers of nuisance defects may be flagged as actual defects when, in fact, the nuisance defects do not affect functionality. Such false flagging of nuisance defects as actual defects reduces accuracy and efficiency by known automatic inspection techniques. Moreover, because nuisance defects may be flagged as actual defects, semiconductor inspection requires considerably more operator time and skill to inspect areas flagged as defective to distinguish nuisance defects from actual defects. Furthermore, the increased presence of these nuisance defects limits how low the defect threshold may be and therefore how sensitive the recipe (e.g., the thresholds and/or parameters associated with detection of actual defects) may be.

Examples disclosed herein simulate completion of semiconductor wafer manufacturing operations to help distinguish between nuisance defects in a structure and actual defects. During manufacture of a semiconductor wafer, a first operation that defines a structure on the semiconductor wafer that causes a structural variation from an expected position and/or dimension often occurs before a second operation (e.g., where an actual defect in the structure may be formed). Examples disclosed herein capture a first image (also referred to herein as a depiction) of the semiconductor wafer and/or a region thereof in response to completion of the first operation. The image of the semiconductor is adjusted to simulate an expected outcome of one or more subsequent manufacturing operations (e.g., a second operation). Examples disclosed herein utilize a neural network and/or procedural code that processes the first image of the semiconductor wafer to predict changes to the structure of the semiconductor wafer and/or region thereof that will occur between completion of the first operation and completion of the second operation. A projected (e.g., an expected) structure of the semiconductor wafer and/or region thereof can include pattern variation that an inspection could capture as a nuisance defect. Furthermore, examples disclosed herein capture a second image of the semiconductor after completion of a subsequent (e.g., second) operation. The projected structure is compared to the second image to identify one or more differences and determine whether an actual defect developed in the semiconductor wafer (e.g., due to completion of the subsequent operation). Because the structural variation from the first operation is captured in the projected structure, the structural anomaly or difference from a design (e.g., a nuisance defect) is not reported as an actual defect. In response to identifying an actual defect, an alert is generated. The alert includes information associated with the identified actual defect(s) (e.g., a location of the actual defect on a wafer or chip, a classification of the actual defect, an impact of the actual defect on a yield of the wafer, etc.). As such, examples disclosed herein help improve accuracy with which actual defects are detected in semiconductor wafer(s) by reducing (e.g., preventing) nuisance defects from being flagged as defective areas or structures.

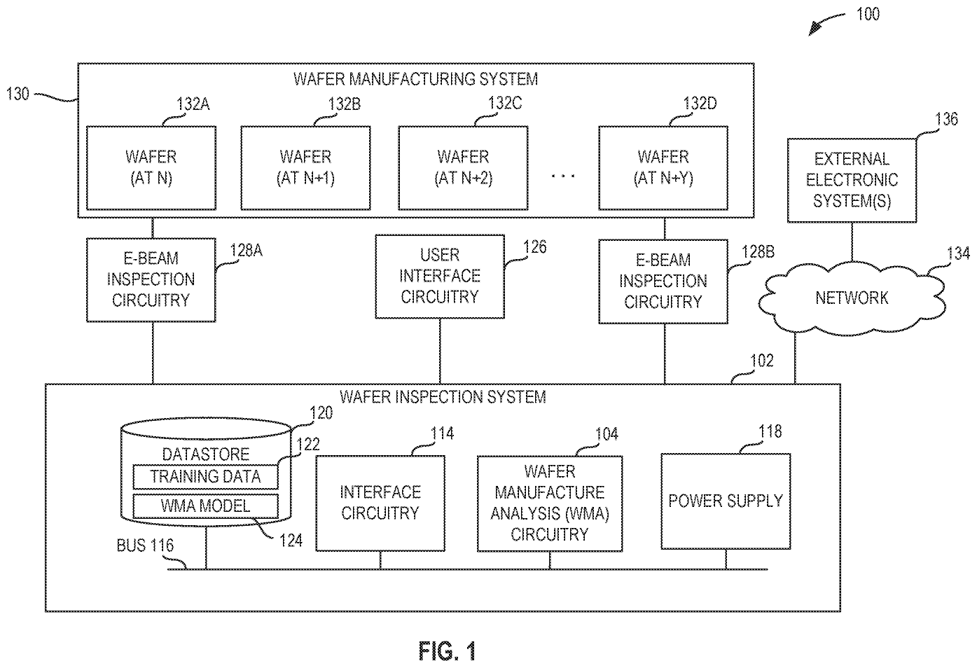

FIG. 1 illustrates an example environment 100 in which an example wafer inspection system 102 operates to inspect wafers and associated manufacturing processes. The example wafer inspection system 102 includes example wafer manufacture analysis (WMA) circuitry 104. The wafer manufacture analysis circuitry 104 of FIG. 1 includes one or more machine learning model(s) that predict a structure of a semiconductor wafer that will result from completion of a wafer manufacturing operation based on an image of the semiconductor wafer obtained after completion of an earlier manufacturing operation. That is, the machine learning model(s) simulate expected results from one or more subsequent manufacturing operation(s) given a current state of the semiconductor wafer. The wafer manufacture analysis circuitry 104 utilizes the expected results by comparing them to actual results (e.g., an image of the semiconductor wafer captured after the one or more subsequent manufacturing operation(s) have been performed) to determine whether an actual defect developed based on a difference between the expected results and the actual results. As a result the wafer manufacture analysis circuitry 104 improves accuracy in detecting defects during manufacturing (e.g., by anticipating nuisance defects and avoiding “false positive” detection thereof).

The wafer inspection system 102 of the illustrated example of FIG. 1 includes the wafer manufacture analysis circuitry 104 (e.g., processor circuitry, a central processing unit (CPU), general purpose processor circuitry, a hardware accelerator, etc.), example interface circuitry 114, an example bus 116, an example power supply 118 (e.g., power circulating circuitry which may be coupled to a source of commercial power), and an example datastore 120. The datastore 120 of the illustrated example of FIG. 1 includes example training data 122 and an example wafer manufacture analysis model 124 (WMA model). As discussed in further detail below, the WMA model 124 is a machine learning model and/or procedural code. Further depicted in the illustrated example of FIG. 1 is example user interface circuitry 126, example electron-beam inspection circuitry 128A-B (e.g., an e-beam tool, an e-beam microscope, etc.), an example semiconductor wafer manufacturing system 130, an example network 134, and example external electronic system(s) 136.

FIG. 1 illustrates an example semiconductor wafer 132 at different manufacturing stages (e.g., 132A-132D). In particular, a first state of the semiconductor wafer 132A occurs after completion of a first wafer manufacturing operation (at N). A second state of the semiconductor wafer 132B occurs after completion of a second wafer manufacturing operation (at N+1) subsequent to the first wafer manufacturing operation (at N). A third state of the semiconductor wafer 132C occurs after completion of a third wafer manufacturing operation (at N+2) subsequent to the second wafer manufacturing operation (at N+1). A fourth state of the semiconductor wafer 132D occurs after completion of another wafer manufacturing operation (at N+Y) subsequent to the first wafer manufacturing operation (at N). The different stages/states of the wafer 132 represent the same wafer at different points in time. Although the second state of the semiconductor wafer 132B and the third state of the semiconductor wafer 132C are shown between the first state 132A and the fourth state 132D, it should be understood that the fourth state of the semiconductor wafer 132D may be representative of the semiconductor wafer 132 at any manufacturing operation (at N+Y) subsequent to the first manufacturing operation (at N).

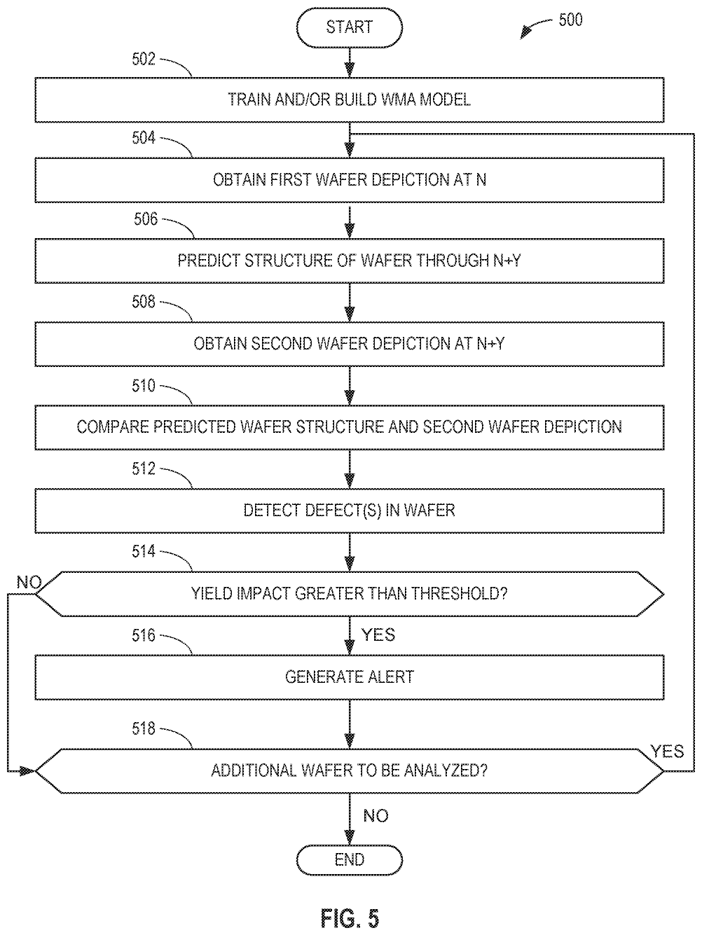

In the illustrated example of FIG. 1, the electron-beam inspection circuitry 128A-B captures information representative of one or more structure(s) of the semiconductor wafer 132. Although not necessarily an optical image, the information collected is referred to as an “image” in this application. The collected information may be any type of data in any form. Furthermore, an “image of a semiconductor wafer” (e.g., the semiconductor wafer 132) corresponds to information associated with at least a portion of the semiconductor wafer and does not necessarily encapsulate the entire semiconductor wafer. Multiple images may capture information associated with different areas of the same semiconductor wafer. Electron-beam inspection circuitry 128A-B captures the image of the semiconductor wafer 132. For example, the electron-beam inspection circuitry 128A-B can capture the image of the semiconductor wafer via a continuous scan, a hot spot scan, and/or a leap and scan method. In this example, first electron-beam inspection circuitry 128A captures a first image of the semiconductor wafer in the first state 132A after completion of a first manufacturing operation (at N). Further, second electron-beam inspection circuitry 128B captures a second image of the semiconductor wafer in another state 132D after completion of another manufacturing operation (at N+Y) subsequent to the first manufacturing operation (at N). In some examples, the electron-beam inspection circuitry 128A-B is instantiated by processor circuitry executing electron-beam inspection instructions and/or configured to perform operations such as those represented by the flowcharts of FIGS. 5 and/or 6.

In the illustrated example of FIG. 1, the wafer inspection system 102 is a software and/or firmware as well as hardware on which the WMA model 124 is trained, deployed, instantiated, and/or executed. The hardware may be special purpose hardware for determining an expected structure of the wafer 132 and/or comparing the expected structure to an actual structure of the wafer. Alternatively, the wafer inspection system 102 may be implemented by a desktop computer, a laptop computer, and/or a server having one or more processors (e.g., a central processing unit (CPU), a digital signal processor (DSP), a graphics processing unit (GPU), a vision processing unit (VPU), an artificial intelligence (AI) and/or neural-network (NN) specific processor, etc.) on one or more system-on-a-chip (SoC) substrates.

In some examples, some or all of the wafer inspection system 102 is implemented on an SoC including one or more integrated circuits (ICs) (e.g., compact ICs) that incorporate circuitry in a compact format. For example, the wafer inspection system 102 may be implemented with a combination of one or more programmable processors, hardware logic, and/or hardware peripherals and/or interfaces. Additionally or alternatively, the example wafer inspection system 102 of FIG. 1 may include memory, input/output (I/O) port(s), and/or secondary storage. For example, the wafer inspection system 102 includes the wafer manufacture analysis circuitry 104, the interface circuitry 114, the bus 116, the power supply 118, the datastore 120, the memory, the I/O port(s), and/or the secondary storage all on the same substrate. In some examples, the wafer inspection system 102 includes digital, analog, mixed-signal, radio frequency (RF), or other signal processing functions.

In some examples, the wafer manufacture analysis circuitry 104 of the illustrated example of FIG. 1 is a programmable processor, such as a CPU, a DSP, or a GPU. In some examples, the wafer manufacture analysis circuitry 104 of the illustrated example of FIG. 1 is a GPU. For example, the wafer manufacture analysis circuitry 104 can be a GPU that is adapted for processing and/or generating computer graphics. In some examples, the wafer manufacture analysis circuitry 104 of the illustrated example of FIG. 1 is a VPU adapted to effectuate machine or computer vision computing tasks. Additionally and/or alternatively, the wafer manufacture analysis circuitry 104 may be a different type of hardware such as a DSP, an application specific integrated circuit (ASIC), a programmable logic device (PLD), and/or a field programmable logic device (FPLD) (e.g., a field-programmable gate array (FPGA)). In some examples, the wafer manufacture analysis circuitry 104 processes AI/ML tasks. For example, the wafer manufacture analysis circuitry 104 can execute and/or otherwise implement a neural network, such as a generative adversarial network (GAN), an artificial neural network (ANN), a convolution neural network (CNN), a deep neural network (DNN), a recurrent neural network (RNN), etc

The interface circuitry 114 is representative of one or more interfaces. For example, the interface circuitry 114 can be implemented by a communication device (e.g., a network interface card (NIC), a smart NIC, an Infrastructure Processing Unit (IPU), etc.) such as a transmitter, a receiver, a transceiver, a modem, a residential gateway, a wireless access point, and/or a network interface to facilitate exchange of data with external machines (e.g., computing devices of any kind). The example interface circuitry 114 receives data from the e-beam inspection circuitry 128A-B. Further, the example interface circuitry 114 transmits information to and receives information from the user interface circuitry 126. The example interface circuitry 114 exchanges information with the external electronic system(s) 136 via the network 134. In some examples, the communication is effectuated via an Ethernet connection, a digital subscriber line (DSL) connection, a telephone line connection, a coaxial cable system, a satellite system, a beyond line-of-site wireless system, a line-of-site wireless system, a cellular telephone system, etc. For example, the interface circuitry 114 can be implemented by any type of interface standard, such as a wireless fidelity (Wi-Fi) interface, an Ethernet interface, a universal serial bus (USB), a Bluetooth interface, a near field communication (NFC) interface, a Peripheral Component Interconnect (PCI) interface, and/or a Peripheral Component Interconnect express (PCI-e or PCIe) interface.

The wafer inspection system 102 of the illustrated example includes the power supply 118 to deliver power to portion(s) of the wafer inspection system 102. In some examples, the power supply 118 is a battery. For example, the power supply 118 can be a limited-energy device, such as a lithium-ion battery or any other chargeable battery or power source. In some examples, the power supply 118 is chargeable using a power adapter or converter (e.g., an alternating current (AC) to direct current (DC) power converter), a wall outlet (e.g., a 120V AC wall outlet, a 224V AC wall outlet, etc.), etc. In some examples, the power supply 118 includes power conditioning circuitry (e.g., a transformer, an amplifier, a filter, etc.) for connecting the wafer inspection system 102 to an external power source such as a commercial power source (e.g., Commonwealth Edison or another power provider).

The wafer inspection system 102 of the illustrated example of FIG. 1 includes the datastore 120 to record data and/or executable instructions (e.g., the training data 122, the WMA model 124, etc.). The datastore 120 may be implemented by a volatile memory (e.g., a Synchronous Dynamic Random Access Memory (SDRAM), Dynamic Random Access Memory (DRAM), RAMBUS Dynamic Random Access Memory (RDRAM), etc.) and/or a non-volatile memory (e.g., flash memory). The datastore 120 may additionally and/or alternatively be implemented by one or more double data rate (DDR) memories, such as DDR, DDR2, DDR3, DDR4, DDR5, mobile DDR (mDDR), etc. The datastore 120 may additionally and/or alternatively be implemented by one or more mass storage devices such as hard disk drive(s) (HDD(s)), compact disk (CD) drive(s), digital versatile disk (DVD) drive(s), solid-state disk (SSD) drive(s), etc. While in the illustrated example, the datastore 120 is illustrated as a single datastore, the datastore 120 may be implemented by any number and/or type(s) of datastores. Furthermore, the data and/or instructions stored in the datastore 120 may be in any data format such as, for example, binary data, comma delimited data, tab delimited data, structured query language (SQL) structures, image file formats (e.g., JPEG, PNG, TIFF, etc.), text formats, scalable vector graphics (SVG) structures, executable files (e.g., AI/ML executable files, AI/ML configuration images, etc.).

In some examples, the datastore 120, and/or, more generally, the wafer inspection system 102, stores the training data 122 to be used as model inputs for training the WMA model 124. For example, the training data 122 can be any type of data, such as images (e.g., image data), numbers (e.g., numerical data), video clips (e.g., video data), labels (e.g., hard labels, soft labels, etc.), etc., and/or any combination thereof. In some examples, image data for semiconductor wafers in association with manufacturing operations performed on the semiconductor wafers is included in the training data 122. Additionally or alternatively, other factors associated with the semiconductor wafers or the performance of the manufacturing operations, such as a wafer material, ambient conditions, etc., can be included in the training data 122. For example, the training data 122 can include respective datasets for respective wafer manufacturing operations performed on certain materials, performed under certain ambient conditions, etc. In some examples, the training data 122 is temporarily accessed over the network 134 and is not downloaded to the datastore 120. In some examples, the wafer inspection system 102 obtains certain portions of the training data 122 via the network 134, the user interface circuitry 126, and/or the e-beam inspection circuitry 128A-B.

In the illustrated example of FIG. 1, the datastore 120, and/or, more generally, the wafer inspection system 102, stores data and/or instructions corresponding to the WMA model 124 to facilitate the training, deployment, and/or execution of the WMA model 124 on the wafer inspection system 102 and/or an external electronic system. In this example, the WMA model 124 is implemented by a GAN. Alternatively, the WMA model 124 may be implemented by set procedural code.

In this example, the WMA model 124 is instantiated and executed by the wafer manufacture analysis circuitry 104. When the WMA model 124 includes a machine learning model, the WMA model 124 can be trained and deployed by the wafer manufacture analysis circuitry 104. For example, the wafer manufacture analysis circuitry 104 can train the WMA model 124 based on the training data 122.

In the illustrated example of FIG. 1, the wafer manufacture analysis circuitry 104 executes the WMA model 124 to detect whether an actual defect developed in the semiconductor wafer 132 after completion of the first wafer manufacturing operation (at N) (e.g., by completion of a second wafer manufacturing operation subsequent to the first wafer manufacturing operation (at N+Y)). For example, using the WMA model 124, the wafer manufacture analysis circuitry 104 predicts a structure of the semiconductor wafer 132 based on first image data of the semiconductor wafer in the first state 132A obtained after completion of the first wafer manufacturing operation (at N). Further, the prediction can based on information associated with a subsequent manufacturing operation (at N+Y) to be performed on the semiconductor wafer 132. The wafer manufacture analysis circuitry 104 can perform a comparison between the predicted structure of the semiconductor wafer 132 and second image data of the semiconductor wafer in another state 132D in response to completion of another wafer manufacturing operation (at N+Y) to detect whether any defects developed in the semiconductor wafer 132 between completion of the first manufacturing operation (at N) and completion of another wafer manufacturing operation (at N+Y).

In the illustrated example of FIG. 1, the wafer inspection system 102 is in communication with the user interface circuitry 126. In some examples, the user interface circuitry 126 is a graphical user interface (GUI), an application display, etc., presented to a user on a display device in circuit with and/or otherwise in communication with the wafer inspection system 102 via one or more display interfaces (e.g., a Video Graphics Array (VGA) interface, a Digital Visual Interface (DVI), a High-Definition Multimedia Interface (HDMI), a DisplayPort interface, etc.).

In the illustrated example of FIG. 1, the wafer manufacture analysis circuitry 104, the interface circuitry 114, the power supply 118, and the datastore 120 are in communication with the bus 116. For example, the bus 116 can correspond to, be representative of, and/or otherwise implement at least one of an Inter-Integrated Circuit (I2C) bus, a Serial Peripheral Interface (SPI) bus, a PCI bus, or a PCIe bus.

In some examples, the network 134 of the illustrated example of FIG. 1 is the Internet. In some examples, the network 134 may be implemented using any suitable wired and/or wireless network(s) including, for example, one or more data buses, one or more Local Area Networks (LANs), one or more wireless LANs, one or more cellular networks, one or more private networks, one or more public networks, one or more satellite networks, etc. The network 134 can enable the wafer inspection system 102 to be in communication with the external electronic system(s) 136. In the illustrated example of FIG. 1, the external electronic system(s) 136 are devices (e.g., computing devices) on which the WMA model 124 can be trained and/or executed to detect whether a defect developed in the semiconductor wafer 132 between completion of a first wafer manufacturing operation (at N) and completion of a second wafer manufacturing operation (at N+Y).

Artificial intelligence (AI), including machine learning (ML), deep learning (DL), and/or other artificial machine-driven logic, enables machines (e.g., computers, logic circuits, etc.) to use a model to process input data to generate an output based on patterns and/or associations previously learned by the model via a training process. For instance, the model may be trained with data to recognize patterns and/or associations and follow such patterns and/or associations when processing input data such that other input(s) result in output(s) consistent with the recognized patterns and/or associations.

Many different types of machine learning models and/or machine learning architectures exist. In some examples disclosed herein, a GAN model can be used to implement the WMA model 124. Using a GAN model enables the wafer manufacture analysis circuitry 104 to predict an appearance of the wafer 132 that simulates completion of a wafer manufacturing operation (e.g., at N+Y) based on an image of the wafer captured after completion of an earlier manufacturing operation (e.g., at N). For example, the first e-beam inspection circuitry 128A can capture the image of the wafer 132. Further, weights and connections in the GAN model can be trained based on changes to the structure of the wafer 132 that result from the wafer manufacture operations performed subsequent to the image being captured (e.g., at N+Y). Specifically, the GAN model is trained to simulate successful performance of the subsequent wafer manufacturing operations (e.g., at N+1, at N+2, at N+Y) that do not result in a defect on the wafer 132. In turn, the wafer manufacture analysis circuitry 104 can execute the GAN model with the image as an input to generate a prediction image representative of successful performance of the subsequent wafer manufacturing operations. As a result, the wafer manufacture analysis circuitry 104 can compare the prediction image to another image of the wafer 132 captured by the second e-beam inspection circuitry 128B after completion of the subsequent wafer manufacturing operations (e.g., at N+Y) to determine whether any actual defects developed in the wafer 132 between completion of the earlier manufacturing operation (at N) and the subsequent manufacturing operation (at N+Y). In general, machine learning models/architectures that are suitable to use in the example approaches disclosed herein will be GANs. However, other types of machine learning models could additionally or alternatively be used such as Generative Models, etc.

In general, implementing a ML/AI system involves two phases, a learning/training phase and an inference phase. In the learning/training phase, a training algorithm is used to train a model to operate in accordance with patterns and/or associations based on, for example, training data. In general, the model includes internal parameters that guide how input data is transformed into output data, such as through a series of nodes and connections within the model to transform input data into output data. Additionally, hyperparameters are used as part of the training process to control how the learning is performed (e.g., a learning rate, a number of layers to be used in the machine learning model, etc.). Hyperparameters are defined to be training parameters that are determined prior to initiating the training process.

Different types of training may be performed based on the type of ML/AI model and/or the expected output. For example, supervised training uses inputs and corresponding expected (e.g., labeled) outputs to select parameters (e.g., by iterating over combinations of select parameters) for the ML/AI model that reduce model error. As used herein, labelling refers to an expected output of the machine learning model (e.g., a classification, an expected output value, etc.). Alternatively, unsupervised training (e.g., used in deep learning, a subset of machine learning, etc.) involves inferring patterns from inputs to select parameters for the ML/AI model (e.g., without the benefit of expected (e.g., labeled) outputs).

When the WMA model 124 is implemented as a GAN, the WMA model 124 includes a generative network and a discriminative network. During the training phase, the discriminative network is trained to differentiate between real and fake renderings of semiconductor wafers that have underwent a successful wafer manufacturing operation (e.g., where an actual defect has not developed on the wafer). Moreover, the generative networks are trained to generate a predicted appearance of the wafer representative of successful performance of a wafer manufacturing operation based on an input image of the wafer prior to the wafer manufacturing operation being performed on the wafer.

In some examples, the WMA model 124 includes respective GANs utilized to predict structural changes in the wafer 132 for certain wafer manufacturing operations and/or certain combinations (e.g., sequences, sets, etc.) of wafer manufacturing operations. Accordingly, the respective discriminative networks associated with the respective GANs are trained to distinguish real images of the wafers depicted in response to completion of respective wafer manufacturing operations. Similarly, the respective generative networks associated with the respective GANs are trained to generate the predicted appearance based on the certain manufacturing operations that the wafer in the input image will have encountered.

In examples disclosed herein, ML/AI models are trained using stochastic gradient descent. However, any other training algorithm may additionally or alternatively be used. In examples disclosed herein, training is performed until the generative network can be used to generate an appearance prediction for a semiconductor wafer (e.g., the wafer 132) associated with completion of a wafer manufacturing operation (e.g., at N+Y) that is indistinguishable from the real appearance of the semiconductor wafer after completion of the wafer manufacturing operation. In examples disclosed herein, training can be performed locally (e.g., at the wafer inspection system 102) and/or remotely (e.g., at the external electronic system(s) 136). Training is performed using hyperparameters that control how the learning is performed (e.g., a learning rate, a number of layers to be used in the machine learning model, etc.). In some examples disclosed herein, hyperparameters control connections and/or weights between the connections in the discriminative network and/or the generative network to help improve an accuracy of predictions formed by the networks. Such hyperparameters are selected by, for example, backpropagation based on results of predictions during training.

For example, during a discriminative network training stage, the discriminative network distinguishes between a real semiconductor wafer image and a fake input generated by the generative network and utilizes backpropagation to adjust weights and/or connections based on a discriminator loss associated with the results. Specifically, the discriminator loss penalizes the discriminative network for misclassifying a real wafer image as fake and classifying the fake input as real.

During a generative network training stage, a wafer image is input into the generative network, which simulates a change in the structure of the wafer in the image based on the image and a wafer manufacturing operation(s) that the wafer is to encounter. Further, the generative network feeds the simulated structure to the discriminative network, which also receives another input of a real image of the wafer taken after successful completion of the wafer manufacturing operation(s). In turn, the discriminative network classifies one of the inputs as real and the other as fake, and a generator loss is calculated based on the results. The generator loss is then backpropagated through the generative network to enable the generative network to adjust weights and/or connections to improve the generator loss.

Furthermore, the discriminative network training and the generative network training can rotate to enable the discriminative network to recognize flaws in the generative network and, in turn, enable the generative network to address such flaws. In some examples disclosed herein, one network remains constant while the other trains. As the generative network improves with training, performance of the discriminative network worsens as the real input image and the generated input image become more difficult to distinguish. As such, convergence of the generative network occurs in a fleeting state and the generative network is deployed in response to the discriminative network having an accuracy of approximately 50%.

In examples disclosed herein, training is performed using training data. In examples disclosed herein, the training data originates from the e-beam inspection circuitry 128A-B and/or the external electronic system(s) 136. The training data includes sample images of semiconductor wafers before and after successful wafer manufacturing operations (e.g., wafer manufacturing operations that did produce actual defects). Because supervised training is used, the training data is labeled. Labeling is applied to the training data by classifying respective wafer manufacturing operations and/or wafer appearances that do not include defects. In some examples, the training data is pre-processed using, for example, the wafer manufacture analysis circuitry 104 and/or the external electronic system(s) 136 to classify sample wafer images based on characteristics associated with the wafer (e.g., a material, a size, etc.), the manufacturing operations performed on the wafer, and/or ambient conditions encountered by the wafers. In some examples, the training data is sub-divided into sample wafer images associated with performance of an individual wafer manufacturing operation and/or sample wafer images associated with a specific material property.

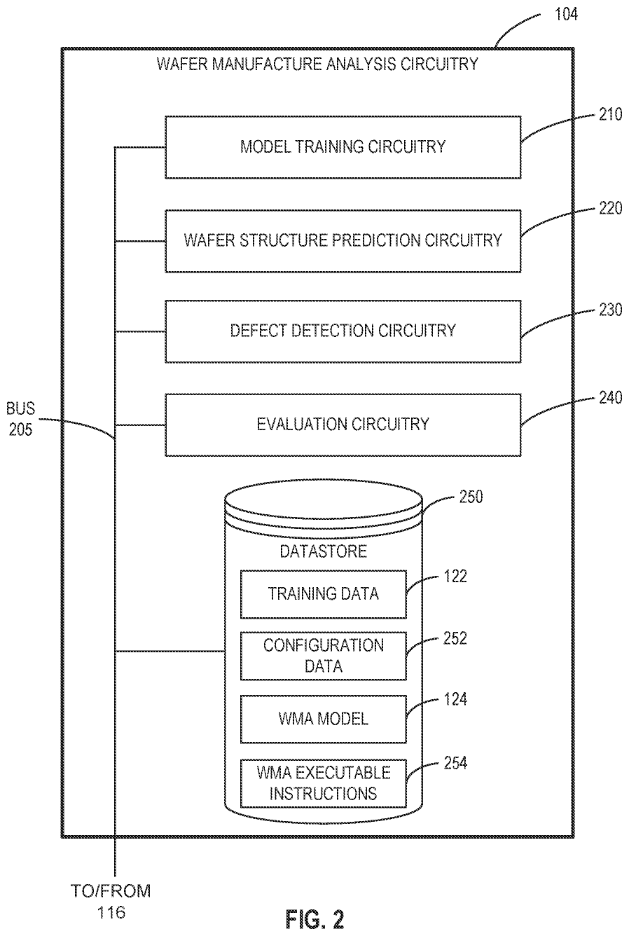

Once training is complete, the model is deployed for use as an executable construct that processes an input and provides an output based on the network of nodes and connections defined in the model. The model is stored at the datastore 120. The model may then be executed by the wafer manufacture analysis circuitry 104. For example, at least a portion of the WMA model 124 can be converted into machine executable instructions, as discussed further in association with FIG. 2.

Once trained, the deployed model may be operated in an inference phase to process data. In the inference phase, data to be analyzed (e.g., live data) is input to the model, and the model executes to create an output. This inference phase can be thought of as the AI “thinking” to generate the output based on what it learned from the training (e.g., by executing the model to apply the learned patterns and/or associations to the live data). In some examples, input data undergoes pre-processing before being used as an input to the machine learning model. Moreover, in some examples, the output data may undergo post-processing after it is generated by the AI model to transform the output into a useful result (e.g., a display of data, an instruction to be executed by a machine, etc.).

In some examples, output of the deployed model may be captured and provided as feedback. By analyzing the feedback, an accuracy of the deployed model can be determined. If the feedback indicates that the accuracy of the deployed model is less than a threshold or other criterion, training of an updated model can be triggered using the feedback and an updated training data set, hyperparameters, etc., to generate an updated, deployed model. In some examples, a difference between the predicted image obtained from the deployed WMA model 124 and the second image of the wafer is determined. In such examples, when an average of the difference over a predetermined number of comparisons does not satisfy (e.g., is less than, is less than or equal to) an average difference threshold, the WMA model 124 can be re-trained with more data added to the training data 122. In some examples, the results obtained from the deployed WMA model 124 are compared to results obtained from electrical signal testing after manufacturing of the corresponding wafer is complete to determine a quantity of false negatives and/or false positives obtained from defect detection after execution of the WMA model 124. When the quantity of false negatives and/or false positives over a predetermined quantity of samples (e.g., wafer inspections) does not satisfy (e.g., is greater than, is greater than or equal to) an error threshold, the WMA model 124 can be re-trained with more data added to the training data 122. In some examples, the WMA model 124 is re-trained in response to an actual defect capture rate (e.g., an accuracy with which actual defects are detected) not satisfying (e.g., being less than, being less than or equal to) a first detection threshold and/or a nuisance flag rate (e.g., a quantity or percentage of flagged actual defects that are nuisance defects) not satisfying (e.g., being greater than, being greater than or equal to) a second detection threshold. In some examples, the images of the wafers associated with false negatives and/or false positives can be added to the training data 122 to enable the WMA model 124 to correct the error previously encountered. Furthermore, the WMA model 124 can be updated or replaced when one or more process steps (e.g., N, N+1, N+2, N+Y) change.

FIG. 2 is a block diagram of an example implementation of the example wafer manufacture analysis circuitry 104 of FIG. 1 to detect defects that developed in the wafer 132 during manufacture. The wafer manufacture analysis circuitry 104 of FIG. 2 may be instantiated (e.g., creating an instance of, bring into being for any length of time, materialize, implement, etc.) by processor circuitry such as a central processing unit executing instructions. Additionally or alternatively, the wafer manufacture analysis circuitry 104 of FIG. 2 may be instantiated (e.g., creating an instance of, bring into being for any length of time, materialize, implement, etc.) by an ASIC or an FPGA structured to perform operations corresponding to the instructions. It should be understood that some or all of the wafer manufacture analysis circuitry 104 of FIG. 2 may, thus, be instantiated at the same or different times. Some or all of the circuitry may be instantiated, for example, in one or more threads executing concurrently on hardware and/or in series on hardware. Moreover, in some examples, some or all of the wafer manufacture analysis circuitry 104 of FIG. 2 may be implemented by microprocessor circuitry executing instructions to implement one or more virtual machines and/or containers.

The wafer manufacture analysis circuitry 104 includes an example bus 205, example model training circuitry 210, example wafer structure prediction circuitry 220, example defect detection circuitry 230, example evaluation circuitry 240, and an example datastore 250. The datastore 250 of the illustrated example includes the training data 122 of FIG. 1, configuration data 252, the WMA model 124 of FIG. 1, and a WMA executable instructions 254. In the illustrated example of FIG. 2, the interface circuitry 114, the model training circuitry 210, the wafer structure prediction circuitry 220, the defect detection circuitry 230, the evaluation circuitry 240, and the datastore 250 are in communication with the bus 205. The bus 205 can correspond to, be representative of, and/or otherwise implement at least one of an Inter-Integrated Circuit (I2C) bus, a Serial Peripheral Interface (SPI) bus, a PCI bus, or a PCIe bus.

In the illustrated example of FIG. 2, the interface circuitry 114 receives data from and/or transmits data to the wafer manufacture analysis circuitry 104. For example, the interface circuitry 114 can receive wafer image data from the e-beam inspection circuitry 128A-B of FIG. 1. In some examples, when the WMA model 124 includes a GAN, the interface circuitry 114 receives the training data 122 (e.g., first wafer image data) for training the WMA model 124. In such examples, the interface circuitry 114 receives classification information associated with sample wafer images in the training data 122. Additionally or alternatively, the interface circuitry 114 receives configuration data 252. In some examples, the configuration data 252 includes information associated with types of semiconductor wafers and/or wafer manufacturing operations to enable the WMA model 124 to correspond with material properties of the wafer 132 and the wafer manufacturing operations (e.g., at N, at N+1, at N+2, at N+Y) being performed on the wafer 132. In some examples, the interface circuitry 114 updates the configuration data 252 based on an input received via the user interface circuitry 126 and/or the external electronic system(s) 136. In some examples, the interface circuitry 114 receives information associated with the wafer 132 and/or the wafer manufacturing operations to be analyzed from the user interface circuitry 126 and/or the external electronic system(s) 136 via the network 134. For example, an operator can indicate information associated with the wafer 132, such as manufacturing operations encountered and/or manufacturing operations yet to be encountered, material properties, and the like, and/or ambient conditions via the user interface circuitry 126. In turn, the interface circuitry 114 can relay the information to the model training circuitry 210 and/or the wafer structure prediction circuitry 220 to enable the WMA model 124 to be adjusted to correspond with given manufacturing operations, material properties, and/or ambient conditions. In some examples, the operator indicates that WMA model 124 is to be utilized over other evaluation models (e.g., a model to perform a design mode comparison, a model to perform an array mode comparison, etc.) via the user interface circuitry 126, and the interface circuitry 114 relays the selection to the wafer manufacture analysis circuitry 104.

Furthermore, the interface circuitry 114 receives second wafer image data (e.g., in response to completion of a first manufacturing operation (at N)) to be utilized for structure prediction. Additionally, the interface circuitry 114 receives third wafer image data (e.g., in response to completion of a subsequent manufacturing operation (at N+Y)) for defect evaluation. In some examples, the interface circuitry 114 receives the image data from the e-beam inspection circuitry 128A-B and/or the network 134. In some examples, the external electronic system(s) 136 build the WMA model 124 and/or the WMA executable instructions 254. In such examples, the interface circuitry 114 receives the WMA model 124 and/or the WMA executable instructions 254 via the network 134.

In some examples, the interface circuitry 114 transmits results obtained from operations performed by the wafer structure prediction circuitry 220, the defect detection circuitry 230, and/or the evaluation circuitry 240 to the user interface circuitry 126 and/or to the external electronic system(s) 136 via the network 134. In some examples, the interface circuitry 114 is instantiated by processor circuitry executing interface instructions and/or configured to perform operations such as those represented by the flowchart of FIGS. 5 and/or 6.

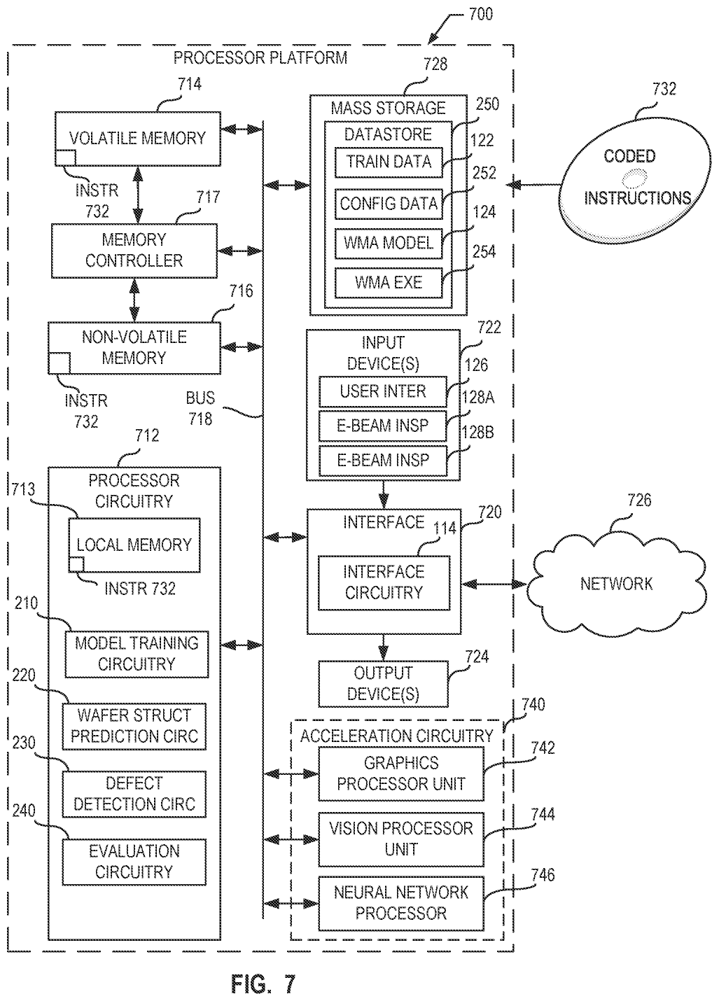

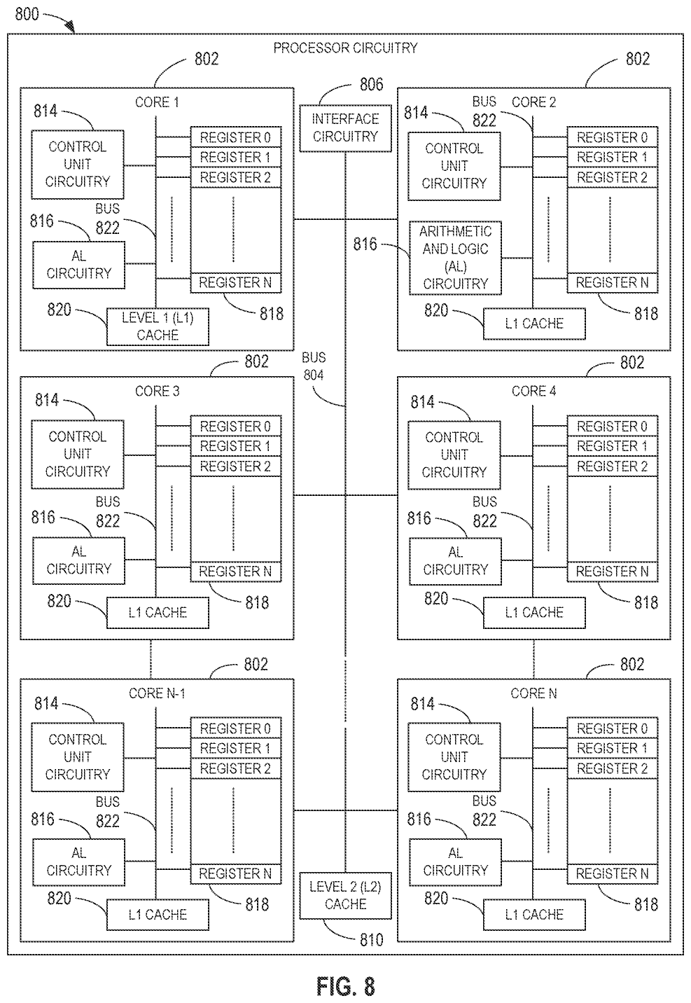

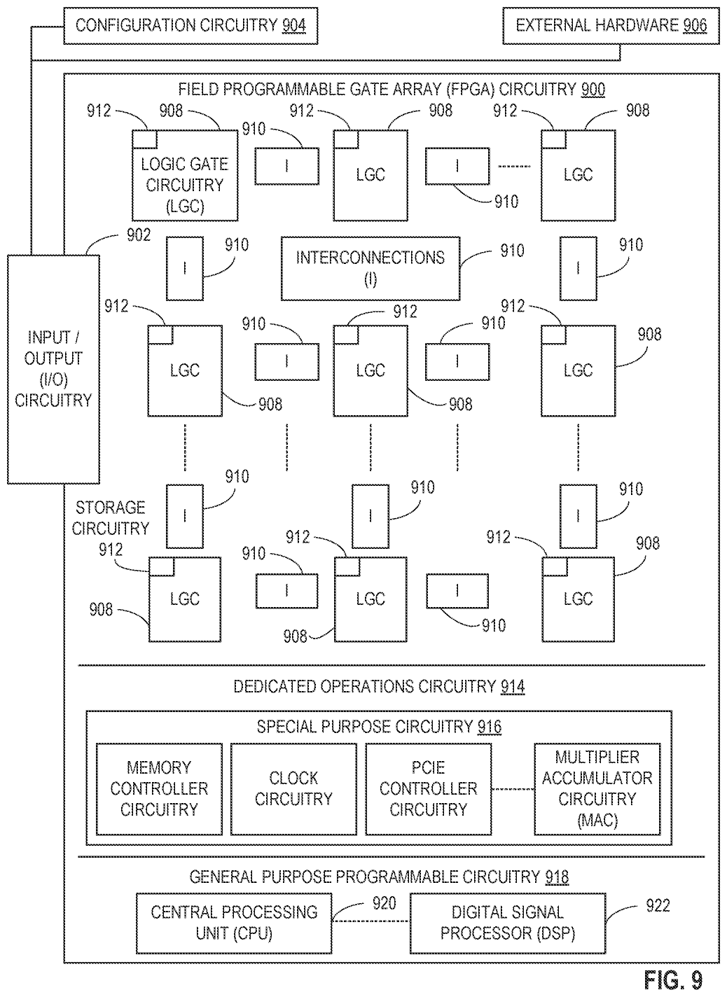

In some examples, the wafer manufacture analysis circuitry 104 includes means for receiving and/or transmitting data. For example, the means for receiving and/or transmitting data may be implemented by the interface circuitry 114. In some examples, the interface circuitry 114 may be instantiated by processor circuitry such as the example processor circuitry 712 of FIG. 7. For instance, the interface circuitry 114 may be instantiated by the example microprocessor 800 of FIG. 8 executing machine executable instructions such as those implemented by at least blocks 502, 504, 508, 516 of FIG. 5. In some examples, the interface circuitry 114 may be instantiated by hardware logic circuitry, which may be implemented by an ASIC, XPU, or the FPGA circuitry 900 of FIG. 9 structured to perform operations corresponding to the machine readable instructions. Additionally or alternatively, the interface circuitry 114 may be instantiated by any other combination of hardware, software, and/or firmware. For example, the interface circuitry 114 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

In some examples, the wafer manufacture analysis circuitry 104 of FIG. 2 includes the model training circuitry 210 to train and/or update the WMA model 124. For example, when the WMA model 124 includes a GAN, the model training circuitry 210 can train the WMA model 124 based on the training data. For example, the model training circuitry 210 can train a first portion (e.g., a discriminate network) of the WMA model 124 to distinguish between real and fake renderings of semiconductor wafers (e.g., the wafer 132 of FIG. 1) that do not have an actual defect after a certain wafer manufacturing operation(s) is encountered by the wafers. Further, a second portion (e.g., a discriminator loss computer) of the WMA model 124 can determine whether the first portion of the WMA model 124 classified the correct input as real and utilize backpropagation to adjust weights and/or connection in the first portion of the WMA model 124 based on whether the classification was correct.

In some examples, the model training circuitry 210 can train a third portion (e.g., a generative network) of the WMA model 124 to generate predicted images of semiconductor wafers (e.g., the wafer 132 of FIG. 1) representative of successful performance of wafer manufacturing operations based on an input image of the semiconductor wafers taken in advance of the wafer manufacturing operations being performed. In such examples, the first portion of the WMA model 124 distinguishes between real wafer images obtained after successful performance of manufacturing operations and predicted images generated by the third portion of the WMA model 124. Specifically, the first portion of the WMA model 124 classifies one of the inputs as real and the other as fake. In turn, a fourth portion (e.g., a generator loss computer) of the WMA model 124 can compute a generator loss based on the wafer image that the first portion of the WMA model 124 classified as real. Further, the generator loss can backpropagate through both the first portion and the third portion to enable the third portion of the WMA model 124 to adjust weights and/or connections in an effort to improve the generator loss. The model training circuitry 210 can rotate between training the first portion of the WMA model 124 and the third portion of the WMA model 124. In some examples, the model training circuitry 210 trains respective GANs of the WMA model 124 to align with a certain wafer material property, certain ambient conditions, and/or a certain wafer manufacturing operation(s). In such examples, the model training circuitry 210 determines which of the respective GANs the WMA model 124 is to utilize for a given manufacture analysis based on the configuration data 252. In some examples, when the WMA model 124 is fully trained, the model training circuitry 210 builds the WMA executable instructions 254 using the third portion of the WMA model 124 based on a configuration input received from the interface circuitry 114 (e.g., material properties of wafers or manufacturing equipment being used, a manufacturing operation(s) being performed, etc.) and the configuration data 252.

In some examples, the WMA model 124 includes procedural code, as discussed in further detail below. In some such examples, the model training circuitry 210 updates the WMA model 124 based on the configuration data 252. For example, the model training circuitry 210 can configure the procedural code in the WMA model 124 based on information associated with the wafer 132, wafer manufacturing operations being performed on the wafer 132, and/or ambient conditions encountered by the wafer 132. Accordingly, the model training circuitry 210 can build the WMA executable 258 based on the WMA model 124 and the configuration data 252. In some examples, the model training circuitry 210 is instantiated by processor circuitry executing model training instructions and/or configured to perform operations such as those represented by the flowchart of FIGS. 5 and/or 6.

In some examples, the wafer manufacture analysis circuitry 104 includes means for training the WMA model 124. For example, the means for training may be implemented by the model training circuitry 210. In some examples, the model training circuitry 210 may be instantiated by processor circuitry such as the example processor circuitry 712 of FIG. 7. For instance, the model training circuitry 210 may be instantiated by the example microprocessor 800 of FIG. 8 executing machine executable instructions such as those implemented by at least block 502 of FIG. 5. In some examples, the model training circuitry 210 may be instantiated by hardware logic circuitry, which may be implemented by an ASIC, XPU, or the FPGA circuitry 900 of FIG. 9 structured to perform operations corresponding to the machine readable instructions. Additionally or alternatively, the model training circuitry 210 may be instantiated by any other combination of hardware, software, and/or firmware. For example, the model training circuitry 210 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

The wafer manufacture analysis circuitry 104 of FIG. 2 includes the wafer structure prediction circuitry 220 to predict a structure of the wafer 132 to result after completion of a later manufacturing operation (at N+Y) (e.g., the state 132D) based on an image of the wafer 132 captured after completion of an earlier manufacturing operation (at N) (e.g., the state 132A). For example, the e-beam inspection circuitry 128A can capture the image of the wafer 132 after completion of the earlier manufacturing operation (at N) (e.g., the wafer 132A). Further, the wafer structure prediction circuitry 220 can execute the WMA executable instructions 254 with the captured image as an input. In turn, the wafer structure prediction circuitry 220 can cause the WMA executable instructions 254 to simulate advancement in the wafer manufacturing process (e.g., development of structures on the wafer 132 across the wafer manufacturing system 130) to determine the predicted structure to result after completion of the later manufacturing operation.

In some examples, the wafer structure prediction circuitry 220 predicts the structure of the wafer 132 before completion of the later manufacturing operation (at N+Y), which enables the predicted structure to be compared to the actual structure of the wafer 132 as soon as possible (e.g., immediately) after completion of the later manufacturing operation (at N+Y). In some examples, the wafer structure prediction circuitry 220 predicts the structure of the wafer 132 simultaneously with the later manufacturing operation (at N+Y) being performed. In such examples, the wafer structure prediction circuitry 220 can update the WMA model 124 and, in turn, the WMA executable instructions 254 based on the ambient conditions encountered at the exact time when the later manufacturing operation (at N+Y) is performed. In some examples, the wafer structure prediction circuitry 220 predicts the structure of the wafer 132 after completion of the later manufacturing operation (at N+Y) (e.g., when defect information is requested after performance of the later manufacturing operation (at N+Y)).

In the illustrated example of FIG. 2, the WMA executable instructions 254 alter the input image based on the later manufacturing operation (at N+Y) and any manufacturing operations performed (at N+1, at N+2) between the earlier manufacturing operation (at N) and the later manufacturing operation (at N+Y). For example, by executing the WMA executable instructions 254, the wafer structure prediction circuitry 220 can cause a first adjustment to the input image based on the manufacturing operation(s) (at N+1, at N+2) performed between the earlier manufacturing operation and the later manufacturing operation to transform the input image into a second image representative of the second state 132B and/or the third state 132C of the wafer 132. Further, by executing the WMA executable instructions 254, the wafer structure prediction circuitry 220 can cause a second adjustment to the second image to generate the predicted structure (e.g., an image representative of the predicted structure) based on the later manufacturing operation (at N+Y). In some examples, the WMA executable instructions 254 consider characteristics of the wafer 132 (e.g., material properties, size, etc.) when simulating changes to be encountered by the wafer 132 during the manufacturing operations (at N+1, at N+2, at N+Y).

In some examples, when the WMA executable instructions 254 include a GAN, the WMA executable instructions 254 have been trained to simulate advancement in the manufacture of the first state 132A of the wafer 132 in the input image based on a structure of the wafer 132 depicted in the input image and the subsequent manufacturing operations to be performed on the wafer 132. As a result, the WMA executable instructions 254 output a wafer appearance prediction (e.g., projected wafer information, an output image) based on the input image and the subsequent manufacturing operations.

In some examples, when the WMA executable instructions 254 include set procedural code, execution of the WMA executable instructions 254 modify the input image based on information associated with the subsequent manufacturing operations to be encountered by the wafer 132. For example, by executing the WMA executable instructions 254, the wafer structure prediction circuitry 220 can shrink a pattern in the image of the wafer 132 (e.g., apply an etch bias) to state a first prediction image of the wafer 132 representative of the wafer 132 having encountered an etching manufacturing operation followed by a resist removal manufacturing operation. Further, by executing the WMA executable instructions 254, the wafer structure prediction circuitry 220 can add sidewalls to edges of the pattern and adjust a contrast of the pattern in the image of the wafer 132 to state a second prediction image of the wafer 132 representative of a new material being added to a surface of the wafer 132. Additionally or alternatively, the transformation from the first prediction image to the second prediction image can be representative of a photoresist on the wafer 132 being replaced by another material as a result of etching. Moreover, by executing the WMA executable instructions 254, the wafer structure prediction circuitry 220 can replace mandrels on the wafer 132 in the second prediction image with a sidewall material having a predetermined thickness to generate a third prediction image of the wafer 132 representative of sidewall deposition and mandrel removal operations being performed on the structure of the wafer 132 shown in the second prediction image. Accordingly, changes to the structure of the wafer 132 in the input image can be associated with dimensions of a pattern, the contrast of the pattern, and/or the addition and/or removal of structures in a prediction image(s) generated by the wafer structure prediction circuitry 220. In some examples, the wafer structure prediction circuitry 220 is instantiated by processor circuitry executing wafer structure prediction instructions and/or configured to perform operations such as those represented by the flowcharts of FIGS. 5 and/or 6.

In some examples, the wafer manufacture analysis circuitry 104 includes means for predicting a structure of a semiconductor wafer. For example, the means for predicting may be implemented by the wafer structure prediction circuitry 220. In some examples, the wafer structure prediction circuitry 220 may be instantiated by processor circuitry such as the example processor circuitry 712 of FIG. 7. For instance, the wafer structure prediction circuitry 220 may be instantiated by the example microprocessor 800 of FIG. 8 executing machine executable instructions such as those implemented by at least block 506 of FIG. 5. In some examples, the wafer structure prediction circuitry 220 may be instantiated by hardware logic circuitry, which may be implemented by an ASIC, XPU, or the FPGA circuitry 900 of FIG. 9 structured to perform operations corresponding to the machine readable instructions. Additionally or alternatively, the wafer structure prediction circuitry 220 may be instantiated by any other combination of hardware, software, and/or firmware. For example, the wafer structure prediction circuitry 220 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

The wafer manufacture analysis circuitry 104 of FIG. 2 includes the defect detection circuitry 230 to determine whether an actual defect developed in the wafer 132D between completion of the earlier manufacturing operation (at N) and the later manufacturing operation (at N+Y). For example, the second e-beam inspection circuitry 128B can capture a second image of the wafer 132D after the later manufacturing operation (at N+Y) is performed on the wafer 132D. Further, the defect detection circuitry 230 can compare the second image of the wafer 132D to the predicted structure generated by the wafer structure prediction circuitry 220. Specifically, the defect detection circuitry 230 compares the predicted structure to a location in the second image where the predicted structure is expected. That is, the location of the predicted structure on the wafer 132 is the location where the predicted structure is expected to be formed (e.g., a location on the wafer 132 captured by the first image). As a result, the defect detection circuitry 230 can compute defect information based on differences between the second image and the predicted structure. That is, the defect detection circuitry 230 analyzes areas of the fourth state of the wafer 132D in the second image that differ from the predicted structure. For example, the defect detection circuitry 230 can compare an area(s) of the wafer 132D occupied by a structure (e.g., word lines) in the second image to an area(s) occupied by a corresponding structure in the predicted image. As a result, the defect detection circuitry 230 can determine an overlap (e.g., an accuracy) of the first areas relative to the second areas, which can be indicative of an accuracy of the later manufacturing operation (at N+Y) and/or the manufacturing operations (at N+1, at N+2) performed between the earlier manufacturing operation (at N) and the later manufacturing operation (at N+Y).

Furthermore, the defect detection circuitry 230 can determine whether a variance between the first areas and the second areas is indicative of an actual defect on the wafer 132D. For example, the defect detection circuitry 230 can determine whether the variance corresponds to a metal tip-to-tip and/or side-to-side short, epitaxy (EPI) shorts, contact-to-gate shorts, word line shorts, and/or the like. In some examples, the defect detection circuitry 230 identifies a defect in the wafer 132D in response to a structure depicted by the second image extending at least a threshold distance past an edge of the corresponding structure in the predicted image. In some examples, the defect detection circuitry 230 evaluates an effectiveness of the manufacturing system 130, and/or operations performed thereby, by comparing the accuracy of the first areas to an accuracy threshold (e.g., a percentage accuracy threshold). In some examples, the defect detection circuitry 230 determines the wafer 132D includes an actual defect when a structure in the second image occupies an area between structures in the predicted image. For example, the gap can correspond to an area between current conducting structures in the wafer 132D. In some examples, the defect detection circuitry 230 determines that the wafer 132D includes an actual defect in response to a structure in the second image not occupying a certain portion of the corresponding structure in the predicted image. For example, the defect detection circuitry 230 can determine that a word line in the wafer 132D does not include a thickness that satisfies (e.g., is greater than, is greater than or equal to) a thickness threshold associated with a conduction or storage capability to be provided by the word lines. Additionally or alternatively, the defect detection circuitry 230 can determine that a word line in the wafer 132D includes a gap separating a first portion of the word line and a second portion of the word line rendering the first portion or the second portion ineffective.

In some examples, the defect detection circuitry 230 determines the threshold corresponding to the defects via the configuration data 252. For example, the defect detection circuitry 230 can determine an allowable variance in the word lines based on information associated with the manufacturing operations and/or the structure being manufactured. In some examples, the defect detection circuitry 230 causes information associated detected defects or a lack thereof to be delivered to the user interface circuitry 126 and/or the external electronic system(s) 136. In some examples, the defect detection circuitry 230 is instantiated by processor circuitry executing defect detection instructions and/or configured to perform operations such as those represented by the flowchart of FIGS. 5 and/or 6.

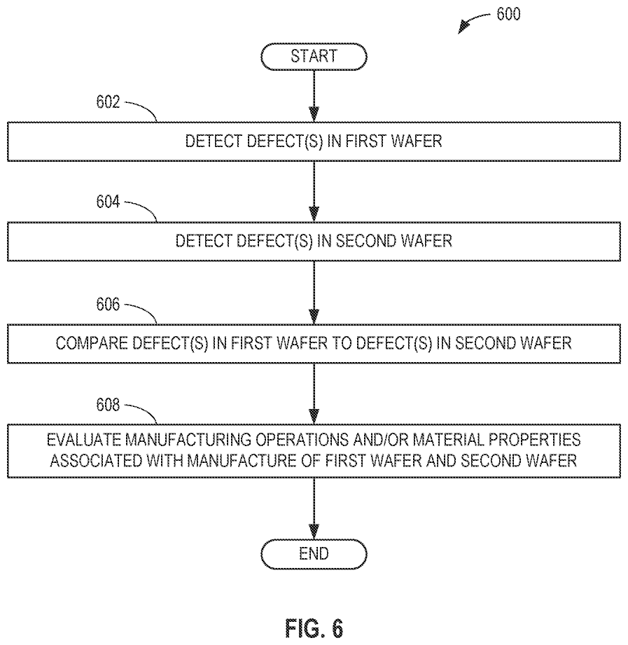

In some examples, the wafer manufacture analysis circuitry 104 includes means for detecting defects in the semiconductor wafer. For example, the means for detecting may be implemented by the defect detection circuitry 230. In some examples, the defect detection circuitry 230 may be instantiated by processor circuitry such as the example processor circuitry 712 of FIG. 7. For instance, the defect detection circuitry 230 may be instantiated by the example microprocessor 800 of FIG. 8 executing machine executable instructions such as those implemented by at least blocks 510, 512 of FIGS. 5 and/or 602, 604 of FIG. 6. In some examples, the defect detection circuitry 230 may be instantiated by hardware logic circuitry, which may be implemented by an ASIC, XPU, or the FPGA circuitry 900 of FIG. 9 structured to perform operations corresponding to the machine readable instructions. Additionally or alternatively, the defect detection circuitry 230 may be instantiated by any other combination of hardware, software, and/or firmware. For example, the defect detection circuitry 230 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

The wafer manufacture analysis circuitry 104 of FIG. 2 includes the evaluation circuitry 240 to evaluate wafer material properties and/or wafer manufacturing operations based on defects detected in association with the wafer material properties and/or the wafer manufacturing operations. For example, a first wafer including a first material property (e.g., formed of a first material) and a second wafer including a second material property (e.g., formed of a second material different from the first material) can go through the same wafer manufacturing operations (e.g., at N, at N+1, at N+2, at N+Y, etc.). In turn, the wafer structure prediction circuitry 220 can project the respective structures of the wafers to result from the manufacturing operations, and the defect detection circuitry 230 can detect first defects that developed in the first wafer and second defects that developed in the second wafer between a beginning and an end of the manufacturing operations, as discussed above. Further, the evaluation circuitry 240 can rank the first material property relative to the second material property based on the first defects and the second defects. For example, the evaluation circuitry 240 can compare a quantity and/or an impact of the first defects to a quantity and/or an impact of the second defects to determine which semiconductor wafer would produce a higher yield and, thus, determine which material property is preferable.

Similarly, first wafer manufacturing operations can be performed on a first wafer and second wafer manufacturing operations designed to produce a structure(s) similar to the first wafer manufacturing operations can be performed on a second wafer. In response to the first wafer and the second wafer being analyzed by the wafer structure prediction circuitry 220 and the defect detection circuitry 230, the evaluation circuitry can determine which manufacturing operations are preferable based on first defects detected in the first wafer and second defects detected in the second wafer. The evaluation circuitry 240 may evaluate the different wafer material properties and/or the different wafer manufacturing operations across sets of wafers to ensure a large enough sample size for an accurate determination as to which material property or manufacturing operation is preferable. In some examples, the evaluation circuitry 240 instantiated by processor circuitry executing defect evaluation instructions and/or configured to perform operations such as those represented by the flowchart of FIG. 6.

In some examples, the wafer manufacture analysis circuitry 104 includes means for evaluating wafer manufacturing operations and/or characteristics of a wafer. For example, the means for evaluating may be implemented by the evaluation circuitry 240. In some examples, the evaluation circuitry 240 may be instantiated by processor circuitry such as the example processor circuitry 712 of FIG. 7. For instance, the evaluation circuitry 240 may be instantiated by the example microprocessor 800 of FIG. 8 executing machine executable instructions such as those implemented by at least blocks 514, 516 of FIG. 5 and/or block 608 of FIG. 6. In some examples, the evaluation circuitry 240 may be instantiated by hardware logic circuitry, which may be implemented by an ASIC, XPU, or the FPGA circuitry 900 of FIG. 9 structured to perform operations corresponding to the machine readable instructions. Additionally or alternatively, the evaluation circuitry 240 may be instantiated by any other combination of hardware, software, and/or firmware. For example, the evaluation circuitry 240 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

The wafer manufacture analysis circuitry 104 of FIG. 2 includes the datastore 250 to record data, such as the training data 122, the configuration data 252, the WMA model 124, the WMA executable instructions 254, etc. The datastore 250 can be implemented by a volatile memory (e.g., a Synchronous Dynamic Random Access Memory (SDRAM), Dynamic Random Access Memory (DRAM), RAMBUS Dynamic Random Access Memory (RDRAM), etc.) and/or a non-volatile memory (e.g., flash memory). The datastore 250 may additionally or alternatively be implemented by one or more double data rate (DDR) memories, such as DDR, DDR2, DDR3, DDR4, DDR5, mobile DDR (mDDR), DDR SDRAM, etc. The datastore 250 may additionally or alternatively be implemented by one or more mass storage devices such as hard disk drive(s) (HDD(s)), compact disk (CD) drive(s), digital versatile disk (DVD) drive(s), solid-state disk (SSD) drive(s), Secure Digital (SD) card(s), CompactFlash (CF) card(s), etc. While in the illustrated example the datastore 250 is illustrated as a single datastore, the datastore 250 may be implemented by any number and/or type(s) of datastores. Furthermore, the data stored in the datastore 250 may be in any data format such as, for example, image data, text data, binary data, comma delimited data, tab delimited data, structured query language (SQL) structures, SVG or SVGZ files, etc.

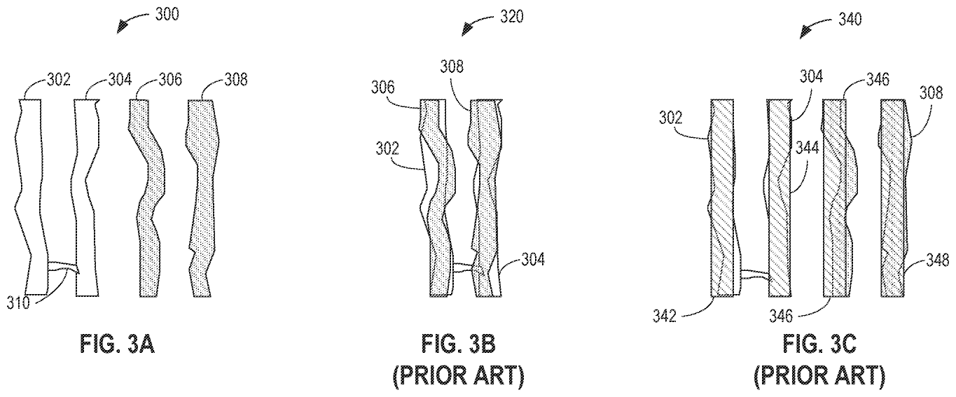

FIG. 3A illustrates an example base pattern 300 of word lines 302, 304, 306, 308 on a semiconductor wafer (e.g., the wafer 132D of FIG. 1). As shown, the base pattern 300 includes a horizontal connection 310 (e.g., a tungsten bridge) between two of the word lines 302, 304. Specifically, the horizontal connection 310 connects adjacent word lines 302, 304 and is representative of a defect that would cause a short in the semiconductor wafer. Such defects have become increasingly difficult to detect with the thickness of word lines (e.g., the word lines 302, 304, 306, 308 of FIG. 3A) continuing to decrease with newer manufacturing technologies as well as horizontal variation (e.g., wiggle) in the word lines 302, 304, 306, 308 having a size about the same as such defects.

FIG. 3B illustrates an example prior art defect inspection mode commonly referred to as array mode inspection 320. The array mode inspection 320 shifts a portion of the word lines (e.g., the word lines 306, 308) to cause the portion of the word lines to overlay another portion of the word lines (e.g., the word lines 302, 304). In turn, the array mode inspection 320 flags areas of the word lines do not match (e.g., that are not overlapped as a result of the overlaying) as defects. However, as shown, the different wiggle in the word lines 302, 304, 306, 308 results in significant variation in some areas other than the horizontal connection 310 and, thus, the array mode inspection 320 can cause frequent false positive errors to be flagged. Moreover, given the variation in the wiggle encountered, attempting to qualify the defects with a stricter threshold (e.g., a stricter parameter(s) indicating when different groups of pixels are to be considered an actual defect) can increase a frequency of false negatives (e.g., more nuisance defects are flagged as actual defects). If a less strict threshold is used so that wiggle is not flagged as an actual defect, then the array mode inspection 320 increases a frequency of false positives (e.g., more actual defects are left undetected) because the variation appears to be similar to variation frequently encountered as a result of the wiggle in the word lines 302, 304, 306, 308.

FIG. 3C illustrates another example prior art defect inspection mode commonly referred to as design comparison mode 340. The design comparison mode 340 compares the word lines 302, 304, 306, 308 to designs 342, 344, 346, 348 that the word lines 302, 304, 306, 308 are intended to match. However, the wiggle in the word lines 302, 304, 306, 308 is not accounted for in the designs 342, 344, 346, 348, which results in acceptable wiggle being incorrectly flagged as a defect.

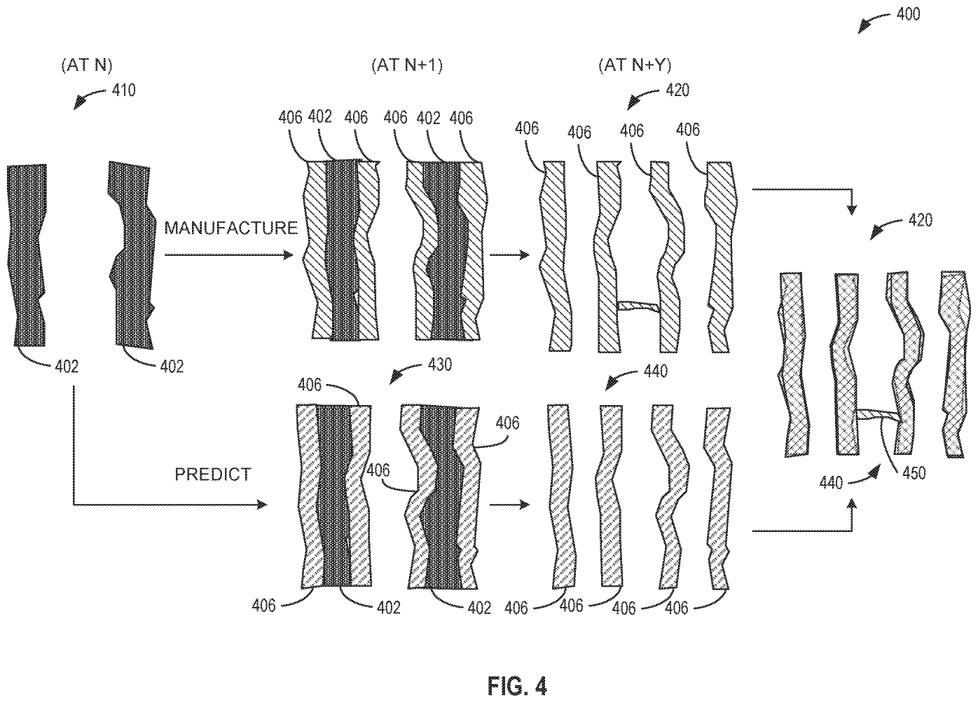

FIG. 4 illustrates an example model inspection mode 400 in accordance with the examples disclosed herein. In the illustrated example of FIG. 4, a manufacturing process is shown in line with a structure prediction generated by the wafer structure prediction circuitry 220. During a first wafer manufacturing operation (at N), a mandrel 402 is formed on a semiconductor wafer (e.g., the wafer 132A). In response to completion of the first wafer manufacturing operation (at N), the first e-beam inspection circuitry 128A captures a first image 410 (e.g., first image data, first structural data, a first image, etc.) of the semiconductor wafer. During a second wafer manufacturing operation (at N+1), a spacer 404 is deposited on the mandrel 402. During a third manufacturing operation (at N+Y), the mandrels 402 are removed and the spacer 404 is etched. In response to completion of the third wafer manufacturing operation (at N+Y), the second e-beam inspection circuitry 128B captures a second image 420 of the semiconductor wafer.

In the illustrated example of FIG. 4, the wafer structure prediction circuitry 220 executes the WMA executable instructions 254 with the first image as an input. As a result, the WMA executable instructions 254 generate a first structural prediction (at N+1) including a simulated deposition of a spacer 406 on the mandrel 402 captured in the first image 410. Specifically, the WMA executable instructions 254 simulate a first change to the first image 410 to generate a third image 430 based on the second wafer manufacturing operation (at N+1). Further, the WMA executable generates a second structural prediction including a simulated removal of the mandrel 402 and etching of the spacer 406. In particular, the WMA executable instructions 254 predict a second change to the third image 430 to generate a fourth image 440 based on the third wafer manufacturing operation (N+Y).

In the illustrated example of FIG. 4, the defect detection circuitry 230 compares the second image 420 and the fourth image 440 to determine whether any defects developed in the semiconductor wafer between the first manufacturing operation (at N) and the third wafer manufacturing operation (at N+Y). As shown, by simulating the manufacture of the semiconductor wafer based on the first image 410, the wafer manufacture analysis circuitry 104 reduces flagged nuisance defects (e.g., false positives) that do not impact a yield of the semiconductor wafer. As a result, the defect detection circuitry 230 is able to detect a defect 450 that developed between completion of the first manufacturing operation (at N) and the third manufacturing operation (at N+Y). As such, the defect 450 can be attributed to the second wafer manufacturing operation (at N+1) and/or the third wafer manufacturing operation (at N+Y).

While an example manner of implementing the wafer manufacture analysis circuitry 104 of FIG. 1 is illustrated in FIG. 2, one or more of the elements, processes, and/or devices illustrated in FIG. 2 may be combined, divided, re-arranged, omitted, eliminated, and/or implemented in any other way. Further, the example interface circuitry 114, the example model training circuitry 210, the example wafer structure prediction circuitry 220, the example defect detection circuitry 230, the example evaluation circuitry 240, the example datastore 250, and/or, more generally, the example wafer manufacture analysis circuitry 104 of FIG. 1, may be implemented by hardware alone or by hardware in combination with software and/or firmware. Thus, for example, any of the example interface circuitry 114, the example model training circuitry 210, the example wafer structure prediction circuitry 220, the example defect detection circuitry 230, the example evaluation circuitry 240, the example datastore 250, and/or, more generally, the example wafer manufacture analysis circuitry 104, could be implemented by processor circuitry, analog circuit(s), digital circuit(s), logic circuit(s), programmable processor(s), programmable microcontroller(s), graphics processing unit(s) (GPU(s)), digital signal processor(s) (DSP(s)), application specific integrated circuit(s) (ASIC(s)), programmable logic device(s) (PLD(s)), and/or field programmable logic device(s) (FPLD(s)) such as Field Programmable Gate Arrays (FPGAs). Further still, the example wafer manufacture analysis circuitry 104 of FIG. 1 may include one or more elements, processes, and/or devices in addition to, or instead of, those illustrated in FIG. 2, and/or may include more than one of any or all of the illustrated elements, processes and devices.

Flowcharts representative of example machine readable instructions, which may be executed to configure processor circuitry to implement the wafer manufacture analysis circuitry 104 of FIGS. 1 and 2, are shown in FIGS. 5-6. The machine readable instructions may be one or more executable programs or portion(s) of an executable program for execution by processor circuitry, such as the processor circuitry 712 shown in the example processor platform 700 discussed below in connection with FIG. 7 and/or the example processor circuitry discussed below in connection with FIGS. 8 and/or 9. The program may be embodied in software stored on one or more non-transitory computer readable storage media such as a compact disk (CD), a floppy disk, a hard disk drive (HDD), a solid-state drive (SSD), a digital versatile disk (DVD), a Blu-ray disk, a volatile memory (e.g., Random Access Memory (RAM) of any type, etc.), or a non-volatile memory (e.g., electrically erasable programmable read-only memory (EEPROM), FLASH memory, an HDD, an SSD, etc.) associated with processor circuitry located in one or more hardware devices, but the entire program and/or parts thereof could alternatively be executed by one or more hardware devices other than the processor circuitry and/or embodied in firmware or dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a user) or an intermediate client hardware device (e.g., a radio access network (RAN)) gateway that may facilitate communication between a server and an endpoint client hardware device). Similarly, the non-transitory computer readable storage media may include one or more mediums located in one or more hardware devices. Further, although the example program is described with reference to the flowcharts illustrated in FIGS. 5-6, many other methods of implementing the example wafer manufacture analysis circuitry 104 may alternatively be used. For example, the order of execution of the blocks may be changed, and/or some of the blocks described may be changed, eliminated, or combined. Additionally or alternatively, any or all of the blocks may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The processor circuitry may be distributed in different network locations and/or local to one or more hardware devices (e.g., a single-core processor (e.g., a single core central processor unit (CPU)), a multi-core processor (e.g., a multi-core CPU, an XPU, etc.) in a single machine, multiple processors distributed across multiple servers of a server rack, multiple processors distributed across one or more server racks, a CPU and/or a FPGA located in the same package (e.g., the same integrated circuit (IC) package or in two or more separate housings, etc.).

The machine readable instructions described herein may be stored in one or more of a compressed format, an encrypted format, a fragmented format, a compiled format, an executable format, a packaged format, etc. Machine readable instructions as described herein may be stored as data or a data structure (e.g., as portions of instructions, code, representations of code, etc.) that may be utilized to create, manufacture, and/or produce machine executable instructions. For example, the machine readable instructions may be fragmented and stored on one or more storage devices and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of machine executable instructions that implement one or more operations that may together form a program such as that described herein.

In another example, the machine readable instructions may be stored in a state in which they may be read by processor circuitry, but require addition of a library (e.g., a dynamic link library (DLL)), a software development kit (SDK), an application programming interface (API), etc., in order to execute the machine readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable media, as used herein, may include machine readable instructions and/or program(s) regardless of the particular format or state of the machine readable instructions and/or program(s) when stored or otherwise at rest or in transit.

The machine readable instructions described herein can be represented by any past, present, or future instruction language, scripting language, programming language, etc. For example, the machine readable instructions may be represented using any of the following languages: C, C++, Java, C #, Perl, Python, JavaScript, HyperText Markup Language (HTML), Structured Query Language (SQL), Swift, etc.

As mentioned above, the example operations of FIGS. 5-6 may be implemented using executable instructions (e.g., computer and/or machine readable instructions) stored on one or more non-transitory computer and/or machine readable media such as optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms non-transitory computer readable medium, non-transitory computer readable storage medium, non-transitory machine readable medium, and non-transitory machine readable storage medium are expressly defined to include any type of computer readable storage device and/or storage disk and to exclude propagating signals and to exclude transmission media. As used herein, the terms “computer readable storage device” and “machine readable storage device” are defined to include any physical (mechanical and/or electrical) structure to store information, but to exclude propagating signals and to exclude transmission media. Examples of computer readable storage devices and machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer readable instructions, machine readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 5 is a flowchart representative of example machine readable instructions and/or example operations 500 that may be executed and/or instantiated by processor circuitry to analyze the structure of a semiconductor wafer for defects during manufacture. The machine readable instructions and/or the operations 500 of FIG. 5 begin at block 502, at which the wafer manufacture analysis circuitry 104 trains and/or builds the WMA model 124. In some examples, the model training circuitry 210 trains one or more GANs to build the WMA model 124. The model training circuitry 210 can build the WMA executable instructions 254 based on the WMA model 124. In some examples, procedural code is built for certain wafer manufacturing operations and/or wafer material properties. In such examples, the model training circuitry 210 can compile the procedural code associated with the material properties of the wafer 132 and/or the wafer manufacturing operations (at N, at N+1, at N+2, at N+Y) to build the WMA executable instructions 254.

At block 504, the wafer manufacture analysis circuitry 104 obtains a first wafer image after completion of a first wafer manufacturing operation (at N). In some examples, the first e-beam inspection circuitry 128A captures the first wafer image.

At block 506, the wafer manufacture analysis circuitry 104 predicts a structure of the wafer 132 through a second wafer manufacturing operation (at N+Y). For example, the wafer structure prediction circuitry 220 can execute the WMA executable instructions 254 with the first wafer image as an input to simulate the second wafer manufacturing operation (at N+Y) and any wafer manufacturing operations (at N+1, at N+2) performed between the first wafer manufacturing operation (at N) and the second wafer manufacturing operation (at N+Y). As a result, the wafer structure prediction circuitry 220 generates a predicted wafer structure.

At block 508, the wafer manufacture analysis circuitry 104 obtains a second wafer image after completion of a second wafer manufacturing operation (at N+Y). In some examples, the second e-beam inspection circuitry 128B captures the second wafer image.

At block 510, the wafer manufacture analysis circuitry 104 compares the predicted wafer structure to the second wafer image. For example, the defect detection circuitry 230 can compare the predicted wafer structure and the second wafer image. In some examples, the defect detection circuitry 230 overlays the predicted wafer structure on the second wafer image to perform the comparison.

At block 512, the wafer manufacture analysis circuitry 104 detects any defects that developed in the wafer 132. For example, the defect detection circuitry 230 can determine whether any actual defects developed between completion of the first wafer manufacturing operation (at N) and completion of a later wafer manufacturing operation (at N+Y) based on differences between the predicted wafer structure and the second wafer image. In some examples, the evaluation circuitry 240 determines whether a size of a structural difference in the second wafer image relative to the predicted wafer structure satisfies (e.g., is greater than, is greater than or equal to) a deviation threshold indicative of the structural deviation being a tungsten bridge that causes a short in the wafer 132D. In some examples, the evaluation circuitry 240 determines a length of the structural difference in a direction perpendicular to a lengthwise span of the corresponding structure (e.g., the word line). In such examples, the evaluation circuitry 240 determines the length of the structural difference corresponds to a defect in response to the length satisfying (e.g., being greater than, being greater than or equal to) a length deviation threshold. For example, the deviation threshold can be based on a size of a gap between adjacent word lines. In some examples, the evaluation circuitry 240 determines an area of a structure in the second wafer image that is outside an expected position of the structure defined by the predicted wafer structure. In such examples, the evaluation circuitry 240 determines the structure represents a defect in response to the area of the structure outside the expected position satisfying (e.g., being greater than, being greater than or equal to) an area deviation threshold. For example, the area deviation threshold can be based on an intended functionality (e.g., conductive properties) of the structure.

At block 514, the wafer manufacture analysis circuitry 104 determines whether an impact of the detected defect(s) is greater than a threshold impact (e.g., a threshold quantity or percentage of integrated circuits on the semiconductor wafer 132). In some examples, the evaluation circuitry 240 determines whether a defect quantity or a percentage of integrated circuits on the semiconductor wafer 132 having a defect satisfies (e.g., is greater than, is greater than or equal to) a threshold. In such examples, the evaluation circuitry 240 may weigh an impact of the detected defects in determining the defect quantity. In response to the detected defect(s) impacting the yield of the wafer 132D, the operations proceed to block 516. Otherwise, the operations 500 skip to block 518.

At block 516, the wafer manufacture analysis circuitry 104 generates an alert. For example, the evaluation circuitry 240 can cause the interface circuitry 114 to deliver an alert to the user interface circuitry 126 and/or the external electronic system(s) 136 in response to the detected defect(s) impacting a yield of the semiconductor wafer 132. In some examples, the evaluation circuitry 540 causes the wafer 132 to be discarded. In some examples, the evaluation circuitry 540 causes an adjustment to be implemented in the second wafer manufacturing operation (at N+Y). In some examples, the evaluation circuitry 540 adjusts one or more material properties provided to subsequent wafers during manufacture.

At block 518, the wafer manufacture analysis circuitry 104 determines whether an additional wafer is to be analyzed in the wafer manufacturing system 130. In response to determining the additional wafer is to be analyzed, the operations 500 return to block 504. Otherwise, the operations 500 terminate.

FIG. 6 is a flowchart representative of example machine readable instructions and/or example operations 600 that may be executed and/or instantiated by processor circuitry to determine preferable wafer manufacturing operations and/or material properties. The machine readable instructions and/or the operations 600 of FIG. 6 begin at block 602, at which the wafer manufacture analysis circuitry 104 detects any first defect(s) in a first semiconductor wafer. For example, the wafer manufacture analysis circuitry 104 can perform the operations 504, 506, 508, 510, 512 of FIG. 5 to detect the first defect(s). In this example, the first semiconductor is formed of a first material having first material properties and/or encounters a first manufacturing process in the wafer manufacturing system 130.

At block 604, the wafer manufacture analysis circuitry 104 detects any second defect(s) in a second semiconductor wafer. For example, the wafer manufacture analysis circuitry 104 can perform the operations 504, 506, 508, 510, 512 of FIG. 5 to detect the second defect(s). In this example, the second semiconductor is formed of a second material having second material properties and/or encounters a second manufacturing process in the wafer manufacturing system 130.

At block 606, the wafer manufacture analysis circuitry 104 compares the first defect(s) to the second defect(s). For example, the evaluation circuitry 240 can compare the first defect(s) to the second defect(s). In some examples, the evaluation circuitry 240 determines a first yield impact associated with the first defect(s) and a second yield impact associated with the second defect(s). In such examples, the evaluation circuitry 240 compares the first yield impact and the second yield impact. Specifically, the first yield impact and the second yield impact are indicative of an effectiveness of the first manufacturing process relative to the second manufacturing process or the first material properties relative to the second material properties. In some examples, the evaluation circuitry 240 compares a quantity of certain defects that impact the yields of the semiconductor wafers, such as word line shorts. In some such examples, the evaluation circuitry 240 assigns weights to the certain defects based on an impact that the certain defects have on the yield of the semiconductor wafer. As such, the evaluation circuitry 240 can multiply the weights by the identified quantity of the respective defects and sum the products to calculate an overall yield impact of the first defect(s) and the second defect(s). In turn, the evaluation circuitry 240 can compare the overall yield impact of the first defect(s) and the second defect(s).

At block 608, the wafer manufacture analysis circuitry 104 evaluates the first and second wafer manufacturing processes and/or the first and second material properties. For example, the evaluation circuitry 240 can determine a preference between (e.g., rank) the first and second wafer manufacturing processes and/or the first and second material properties based on the comparison between the first defect(s) and the second defect(s). That is, the wafer manufacture analysis circuitry 104 can determine that a specific manufacturing operation in the first and/or second manufacturing processes caused the defect(s) and/or determine that certain material properties helped prevent the defect(s). In some examples, the evaluation circuitry 240 determines manufacturing operations that are to be adjusted and/or monitored for defects based on the first defect(s) and/or the second defect(s). For example, the first manufacturing process can include a first manufacturing operation, and the second manufacturing process can include a second wafer manufacturing operation in replacement of the first wafer manufacturing operation. As such, the evaluation circuitry 240 can identify whether the first manufacturing operation or the second wafer manufacturing operation is preferred based on the first defect(s) and the second defect(s).

Alternatively, the first manufacturing process can include first and second manufacturing operations, and the second manufacturing process can include the first and the second manufacturing operations as well as third and fourth manufacturing operations. In response to the second defect(s) having a worse yield impact than the first defect(s), the wafer manufacture analysis circuitry 104 can determine that the third and fourth manufacturing operations produced certain yield impacting defects. As a result, the wafer manufacture analysis circuitry 104 can determine that, during a subsequent wafer manufacture analysis, the third and fourth manufacturing operations are to be individually monitored. That is, the e-beam inspection circuitry 128A-B can be positioned to capture images of wafers before and after completion of the third and fourth manufacturing operations to enable the wafer manufacture analysis circuitry 104 to identify the defects caused by the respective manufacturing operations.

FIG. 7 is a block diagram of an example processor platform 700 structured to execute and/or instantiate the machine readable instructions and/or the operations of FIGS. 5-6 to implement the wafer manufacture analysis circuitry 104 of FIGS. 1 and 2. The processor platform 700 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a digital video recorder, or any other type of computing device.

The processor platform 700 of the illustrated example includes processor circuitry 712. The processor circuitry 712 of the illustrated example is hardware. For example, the processor circuitry 712 can be implemented by one or more integrated circuits, logic circuits, FPGAs, microprocessors, CPUs, GPUs, DSPs, and/or microcontrollers from any desired family or manufacturer. The processor circuitry 712 may be implemented by one or more semiconductor based (e.g., silicon based) devices. In this example, the processor circuitry 712 implements the model training circuitry 210, the wafer structure prediction circuitry 220, the defect detection circuitry 230, and the evaluation circuitry 240.

The processor circuitry 712 of the illustrated example includes a local memory 713 (e.g., a cache, registers, etc.). The processor circuitry 712 of the illustrated example is in communication with a main memory including a volatile memory 714 and a non-volatile memory 716 by a bus 718. The volatile memory 714 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 716 may be implemented by flash memory and/or any other desired type of memory device. Access to the main memory 714, 716 of the illustrated example is controlled by a memory controller 717.

The processor platform 700 of the illustrated example also includes interface circuitry 720. The interface circuitry 720 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 722 are connected to the interface circuitry 720. The input device(s) 722 permit(s) a user to enter data and/or commands into the processor circuitry 712. The input device(s) 722 can be implemented by, for example, an electron-beam tool (e.g., an electron-beam microscope), an audio sensor, a microphone, a camera (still or video), a keyboard, a button, a mouse, a touchscreen, a track-pad, a trackball, an isopoint device, and/or a voice recognition system. In this example, the input device(s) 722 implement the user interface circuitry 126 and the e-beam inspection circuitry 128A-B.

One or more output devices 724 are also connected to the interface circuitry 720 of the illustrated example. The output device(s) 724 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 720 of the illustrated example, thus, typically includes a graphics driver card, a graphics driver chip, and/or graphics processor circuitry such as a GPU.

The interface circuitry 720 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 726. The communication can be by, for example, an Ethernet connection, a digital subscriber line (DSL) connection, a telephone line connection, a coaxial cable system, a satellite system, a line-of-site wireless system, a cellular telephone system, an optical connection, etc. In this example, the interface circuitry 720 implements the interface circuitry 114.

The processor platform 700 of the illustrated example also includes one or more mass storage devices 728 to store software and/or data. Examples of such mass storage devices 728 include magnetic storage devices, optical storage devices, floppy disk drives, HDDs, CDs, Blu-ray disk drives, redundant array of independent disks (RAID) systems, solid state storage devices such as flash memory devices and/or SSDs, and DVD drives. In this example, the mass storage devices 728 implement the datastore 250 including the training data 122, the configuration data 252, the WMA model 124, and the WMA executable instructions 254.

The machine readable instructions 732, which may be implemented by the machine readable instructions of FIGS. 5-6, may be stored in the mass storage device 728, in the volatile memory 714, in the non-volatile memory 716, and/or on a removable non-transitory computer readable storage medium such as a CD or DVD.

The processor platform 700 of the illustrated example of FIG. 7 includes example acceleration circuitry 738, which includes an example graphics processing unit (GPU) 740, an example vision processing unit (VPU) 742, and an example neural network processor 744. In this example, the GPU 740, the VPU 742, and the neural network processor 744 are in communication with different hardware of the processor platform 700, such as the volatile memory 714, the non-volatile memory 716, etc., via the bus 718. In this example, the neural network processor 744 may be implemented by one or more integrated circuits, logic circuits, microprocessors, GPUs, DSPs, or controllers from any desired family or manufacturer that can be used to execute an AI model, such as a neural network, which may be implemented by the WMA model 124. In some examples, one or more of the example model training circuitry 210, the example wafer structure prediction circuitry 220, the example defect detection circuitry 230, the example evaluation circuitry 240 can be implemented in or with at least one of the GPU 740, the VPU 742, or the neural network processor 744 instead of or in addition to the processor circuitry 712.

In some examples, the GPU 740 may implement the wafer manufacture analysis circuitry 104 of FIG. 1. In some examples, the VPU 742 may implement the wafer manufacture analysis circuitry 104 of FIG. 1. In some examples, the neural network processor 744 may implement the wafer manufacture analysis circuitry 104 of FIG. 1.

FIG. 8 is a block diagram of an example implementation of the processor circuitry 712 of FIG. 7. In this example, the processor circuitry 712 of FIG. 7 is implemented by a microprocessor 800. For example, the microprocessor 800 may be a general purpose microprocessor (e.g., general purpose microprocessor circuitry). The microprocessor 800 executes some or all of the machine readable instructions of the flowcharts of FIGS. 5-6 to effectively instantiate the wafer manufacture analysis circuitry 104 of FIGS. 1 and 2 as logic circuits to perform the operations corresponding to those machine readable instructions. In some such examples, the circuitry of FIG. 2 [er diagram] is instantiated by the hardware circuits of the microprocessor 800 in combination with the instructions. For example, the microprocessor 800 may be implemented by multi-core hardware circuitry such as a CPU, a DSP, a GPU, an XPU, etc. Although it may include any number of example cores 802 (e.g., 1 core), the microprocessor 800 of this example is a multi-core semiconductor device including N cores. The cores 802 of the microprocessor 800 may operate independently or may cooperate to execute machine readable instructions. For example, machine code corresponding to a firmware program, an embedded software program, or a software program may be executed by one of the cores 802 or may be executed by multiple ones of the cores 802 at the same or different times. In some examples, the machine code corresponding to the firmware program, the embedded software program, or the software program is split into threads and executed in parallel by two or more of the cores 802. The software program may correspond to a portion or all of the machine readable instructions and/or operations represented by the flowcharts of FIGS. 5-6.

The cores 802 may communicate by a first example bus 804. In some examples, the first bus 804 may be implemented by a communication bus to effectuate communication associated with one(s) of the cores 802. For example, the first bus 804 may be implemented by at least one of an Inter-Integrated Circuit (I2C) bus, a Serial Peripheral Interface (SPI) bus, a PCI bus, or a PCIe bus. Additionally or alternatively, the first bus 804 may be implemented by any other type of computing or electrical bus. The cores 802 may obtain data, instructions, and/or signals from one or more external devices by example interface circuitry 806. The cores 802 may output data, instructions, and/or signals to the one or more external devices by the interface circuitry 806. Although the cores 802 of this example include example local memory 820 (e.g., Level 1 (L1) cache that may be split into an L1 data cache and an L1 instruction cache), the microprocessor 800 also includes example shared memory 810 that may be shared by the cores (e.g., Level 2 (L2 cache)) for high-speed access to data and/or instructions. Data and/or instructions may be transferred (e.g., shared) by writing to and/or reading from the shared memory 810. The local memory 820 of each of the cores 802 and the shared memory 810 may be part of a hierarchy of storage devices including multiple levels of cache memory and the main memory (e.g., the main memory 714, 716 of FIG. 7). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 802 may be referred to as a CPU, DSP, GPU, etc., or any other type of hardware circuitry. Each core 802 includes control unit circuitry 814, arithmetic and logic (AL) circuitry (sometimes referred to as an ALU) 816, a plurality of registers 818, the local memory 820, and a second example bus 822. Other structures may be present. For example, each core 802 may include vector unit circuitry, single instruction multiple data (SIMD) unit circuitry, load/store unit (LSU) circuitry, branch/jump unit circuitry, floating-point unit (FPU) circuitry, etc. The control unit circuitry 814 includes semiconductor-based circuits structured to control (e.g., coordinate) data movement within the corresponding core 802. The AL circuitry 816 includes semiconductor-based circuits structured to perform one or more mathematic and/or logic operations on the data within the corresponding core 802. The AL circuitry 816 of some examples performs integer based operations. In other examples, the AL circuitry 816 also performs floating point operations. In yet other examples, the AL circuitry 816 may include first AL circuitry that performs integer based operations and second AL circuitry that performs floating point operations. In some examples, the AL circuitry 816 may be referred to as an Arithmetic Logic Unit (ALU). The registers 818 are semiconductor-based structures to store data and/or instructions such as results of one or more of the operations performed by the AL circuitry 816 of the corresponding core 802. For example, the registers 818 may include vector register(s), SIMD register(s), general purpose register(s), flag register(s), segment register(s), machine specific register(s), instruction pointer register(s), control register(s), debug register(s), memory management register(s), machine check register(s), etc. The registers 818 may be arranged in a bank as shown in FIG. 8. Alternatively, the registers 818 may be organized in any other arrangement, format, or structure including distributed throughout the core 802 to shorten access time. The second bus 822 may be implemented by at least one of an I2C bus, a SPI bus, a PCI bus, or a PCIe bus

Each core 802 and/or, more generally, the microprocessor 800 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 800 is a semiconductor device fabricated to include many transistors interconnected to implement the structures described above in one or more integrated circuits (ICs) contained in one or more packages. The processor circuitry may include and/or cooperate with one or more accelerators. In some examples, accelerators are implemented by logic circuitry to perform certain tasks more quickly and/or efficiently than can be done by a general purpose processor. Examples of accelerators include ASICs and FPGAs such as those discussed herein. A GPU or other programmable device can also be an accelerator. Accelerators may be on-board the processor circuitry, in the same chip package as the processor circuitry and/or in one or more separate packages from the processor circuitry.

FIG. 9 is a block diagram of another example implementation of the processor circuitry 712 of FIG. 7. In this example, the processor circuitry 712 is implemented by FPGA circuitry 900. For example, the FPGA circuitry 900 may be implemented by an FPGA. The FPGA circuitry 900 can be used, for example, to perform operations that could otherwise be performed by the example microprocessor 800 of FIG. 8 executing corresponding machine readable instructions. However, once configured, the FPGA circuitry 900 instantiates the machine readable instructions in hardware and, thus, can often execute the operations faster than they could be performed by a general purpose microprocessor executing the corresponding software.

More specifically, in contrast to the microprocessor 800 of FIG. 8 described above (which is a general purpose device that may be programmed to execute some or all of the machine readable instructions represented by the flowcharts of FIGS. 5-6 but whose interconnections and logic circuitry are fixed once fabricated), the FPGA circuitry 900 of the example of FIG. 9 includes interconnections and logic circuitry that may be configured and/or interconnected in different ways after fabrication to instantiate, for example, some or all of the machine readable instructions represented by the flowcharts of FIGS. 5-6. In particular, the FPGA circuitry 900 may be thought of as an array of logic gates, interconnections, and switches. The switches can be programmed to change how the logic gates are interconnected by the interconnections, effectively forming one or more dedicated logic circuits (unless and until the FPGA circuitry 900 is reprogrammed). The configured logic circuits enable the logic gates to cooperate in different ways to perform different operations on data received by input circuitry. Those operations may correspond to some or all of the software represented by the flowcharts of FIGS. 5-6. As such, the FPGA circuitry 900 may be structured to effectively instantiate some or all of the machine readable instructions of the flowcharts of FIGS. 5-6 as dedicated logic circuits to perform the operations corresponding to those software instructions in a dedicated manner analogous to an ASIC. Therefore, the FPGA circuitry 900 may perform the operations corresponding to the some or all of the machine readable instructions of FIGS. 5-6 faster than the general purpose microprocessor can execute the same.

In the example of FIG. 9, the FPGA circuitry 900 is structured to be programmed (and/or reprogrammed one or more times) by an end user by a hardware description language (HDL) such as Verilog. The FPGA circuitry 900 of FIG. 9, includes example input/output (I/O) circuitry 902 to obtain and/or output data to/from example configuration circuitry 904 and/or external hardware 906. For example, the configuration circuitry 904 may be implemented by interface circuitry that may obtain machine readable instructions to configure the FPGA circuitry 900, or portion(s) thereof. In some such examples, the configuration circuitry 904 may obtain the machine readable instructions from a user, a machine (e.g., hardware circuitry (e.g., programmed or dedicated circuitry) that may implement an Artificial Intelligence/Machine Learning (AI/ML) model to generate the instructions), etc. In some examples, the external hardware 906 may be implemented by external hardware circuitry. For example, the external hardware 906 may be implemented by the microprocessor 800 of FIG. 8. The FPGA circuitry 900 also includes an array of example logic gate circuitry 908, a plurality of example configurable interconnections 910, and example storage circuitry 912. The logic gate circuitry 908 and the configurable interconnections 910 are configurable to instantiate one or more operations that may correspond to at least some of the machine readable instructions of FIGS. 5-6 and/or other desired operations. The logic gate circuitry 908 shown in FIG. 9 is fabricated in groups or blocks. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 908 to enable configuration of the electrical structures and/or the logic gates to form circuits to perform desired operations. The logic gate circuitry 908 may include other electrical structures such as look-up tables (LUTs), registers (e.g., flip-flops or latches), multiplexers, etc.

The configurable interconnections 910 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 908 to program desired logic circuits.

The storage circuitry 912 of the illustrated example is structured to store result(s) of the one or more of the operations performed by corresponding logic gates. The storage circuitry 912 may be implemented by registers or the like. In the illustrated example, the storage circuitry 912 is distributed amongst the logic gate circuitry 908 to facilitate access and increase execution speed.

The example FPGA circuitry 900 of FIG. 9 also includes example Dedicated Operations Circuitry 914. In this example, the Dedicated Operations Circuitry 914 includes special purpose circuitry 916 that may be invoked to implement commonly used functions to avoid the need to program those functions in the field. Examples of such special purpose circuitry 916 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 900 may also include example general purpose programmable circuitry 918 such as an example CPU 920 and/or an example DSP 922. Other general purpose programmable circuitry 918 may additionally or alternatively be present such as a GPU, an XPU, etc., that can be programmed to perform other operations.

Although FIGS. 5 and 6 illustrate two example implementations of the processor circuitry 712 of FIG. 7, many other approaches are contemplated. For example, as mentioned above, modern FPGA circuitry may include an on-board CPU, such as one or more of the example CPU 920 of FIG. 9. Therefore, the processor circuitry 712 of FIG. 7 may additionally be implemented by combining the example microprocessor 800 of FIG. 8 and the example FPGA circuitry 900 of FIG. 9. In some such hybrid examples, a first portion of the machine readable instructions represented by the flowcharts of FIGS. 5-6 may be executed by one or more of the cores 802 of FIG. 8, a second portion of the machine readable instructions represented by the flowcharts of FIGS. 5-6 may be executed by the FPGA circuitry 900 of FIG. 9, and/or a third portion of the machine readable instructions represented by the flowcharts of FIGS. 5-6 may be executed by an ASIC. It should be understood that some or all of the circuitry of FIG. 2 may, thus, be instantiated at the same or different times. Some or all of the circuitry may be instantiated, for example, in one or more threads executing concurrently and/or in series. Moreover, in some examples, some or all of the wafer manufacture analysis circuitry 104 of FIGS. 1 and 2 may be implemented within one or more virtual machines and/or containers executing on the microprocessor.

In some examples, the processor circuitry 712 of FIG. 7 may be in one or more packages. For example, the microprocessor 800 of FIG. 8 and/or the FPGA circuitry 900 of FIG. 9 may be in one or more packages. In some examples, an XPU may be implemented by the processor circuitry 712 of FIG. 7, which may be in one or more packages. For example, the XPU may include a CPU in one package, a DSP in another package, a GPU in yet another package, and an FPGA in still yet another package.

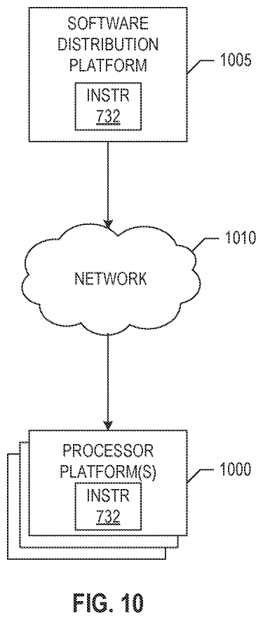

A block diagram illustrating an example software distribution platform 1005 to distribute software such as the example machine readable instructions 732 of FIG. 7 to hardware devices owned and/or operated by third parties is illustrated in FIG. 10. The example software distribution platform 1005 may be implemented by any computer server, data facility, cloud service, etc., capable of storing and transmitting software to other computing devices. The third parties may be customers of the entity owning and/or operating the software distribution platform 1005. For example, the entity that owns and/or operates the software distribution platform 1005 may be a developer, a seller, and/or a licensor of software such as the example machine readable instructions 732 of FIG. 7. The third parties may be consumers, users, retailers, OEMs, etc., who purchase and/or license the software for use and/or re-sale and/or sub-licensing. In the illustrated example, the software distribution platform 1005 includes one or more servers and one or more storage devices. The storage devices store the machine readable instructions 1032, which may correspond to the example machine readable instructions 500, 600 of FIGS. 5-6, as described above. The one or more servers of the example software distribution platform 1005 are in communication with an example network 1010, which may correspond to any one or more of the Internet and/or any of the example network 726 described above. In some examples, the one or more servers are responsive to requests to transmit the software to a requesting party as part of a commercial transaction. Payment for the delivery, sale, and/or license of the software may be handled by the one or more servers of the software distribution platform and/or by a third party payment entity. The servers enable purchasers and/or licensors to download the machine readable instructions 732 from the software distribution platform 1005. For example, the software, which may correspond to the example machine readable instructions 500, 600 of FIGS. 5-6, may be downloaded to the example processor platform 700, which is to execute the machine readable instructions 732 to implement the wafer manufacture analysis circuitry 104. In some examples, one or more servers of the software distribution platform 1005 periodically offer, transmit, and/or force updates to the software (e.g., the example machine readable instructions 732 of FIG. 7) to ensure improvements, patches, updates, etc., are distributed and applied to the software at the end user devices.

From the foregoing, it will be appreciated that example systems, methods, apparatus, and articles of manufacture have been disclosed that inspect semiconductor wafers and avoid identifying nuisance defects and/or the like as actual defects. Examples disclosed herein predict changes to a structure of a semiconductor wafer and/or portion thereof based on a first image of the wafer and information associated with subsequent manufacturing operations to be encountered by the wafer. As a result, a projected structure of the semiconductor wafer and/or region thereof is generated with pattern variability that is expected to occur given the structure of the wafer depicted in the first image. In turn, the projected structure is compared to a second image of the semiconductor captured after completion of the subsequent manufacturing operations to detect whether any defects developed outside of the expected pattern variability.

Example methods, apparatus, systems, and articles of manufacture to inspect semiconductor wafers are disclosed herein. Further examples and combinations thereof include the following:

Example 1 includes an apparatus comprising memory, machine readable instructions, and processor circuitry to at least one of instantiate operations corresponding to the machine readable instructions or execute the machine readable instructions to predict a structure of a semiconductor wafer that is to result from a second wafer manufacturing operation based on a first image of the semiconductor wafer obtained after a first wafer manufacturing operation, the second wafer manufacturing operation to be performed subsequent to the first wafer manufacturing operation, and determine whether an actual defect developed in the semiconductor wafer between completion of the first wafer manufacturing operation and completion of the second wafer manufacturing operation based on the predicted structure of the semiconductor wafer and a second image representative of the semiconductor wafer after completion of the second wafer manufacturing operation.

Example 2 includes the apparatus of example 1, at least one of a bridge that connects a first word line and a second word line in the semiconductor wafer, a metal tip-to-tip short, a metal side-to-side short, an epitaxy short, or a contact-to-gate short.

Example 3 includes the apparatus of example 1, wherein, to predict the structure of the semiconductor wafer, the processor circuitry is to simulate a change in the first image that is to occur during at least the second wafer manufacturing operation using a generative adversarial network.

Example 4 includes the apparatus of example 1, wherein, to predict the structure of the semiconductor wafer, the processor circuitry is to transform the first image into a third image representative of the predicted structure based on the second wafer manufacturing operation.

Example 5 includes the apparatus of example 1, wherein, to predict the structure of the semiconductor wafer, the processor circuitry is to cause a first adjustment to the first image to generate a third image based on a third wafer manufacturing operation performed between the first wafer manufacturing operation and the second wafer manufacturing operation, and cause a second adjustment to the third image to generate the predicted structure based on the second wafer manufacturing operation.

Example 6 includes the apparatus of example 1, wherein the processor circuitry is to obtain the first image and the second image via an electron-beam microscope.

Example 7 includes the apparatus of example 1, wherein the processor circuitry is to generate an alert in response to detection of the actual defect.

Example 8 includes the apparatus of example 1, wherein the semiconductor wafer is a first semiconductor wafer, and the actual defect is a first set of actual defects, wherein the processor circuitry is to obtain a third image of a second semiconductor wafer after a third wafer manufacturing operation, wherein the third wafer manufacturing operation is in replacement of the second wafer manufacturing operation, and perform a comparison between the predicted structure and the third image to determine whether a second set of actual defects developed in the second semiconductor wafer between the first wafer manufacturing operation and the third wafer manufacturing operation.

Example 9 includes the apparatus of example 8, wherein the first set of actual defects includes a first quantity of defects and the second set of actual defects includes a second quantity of defects, and wherein the second quantity of defects and the first quantity of defects are indicative of an effectiveness of the third wafer manufacturing operation relative to the second wafer manufacturing operation.

Example 10 includes the apparatus of example 1, wherein the processor circuitry is to predict the structure of the semiconductor wafer before completion of the second wafer manufacturing operation and after completion of the first wafer manufacturing operation.

Example 11 includes the apparatus of example 1, wherein the processor circuitry is to compare the predicted structure to a corresponding structure in the second image, the corresponding structure in a location on the semiconductor wafer where the predicted structure is expected.

Example 12 includes a non-transitory machine readable storage medium comprising instructions that, when executed, cause processor circuitry to at least simulate advancement in a manufacturing process of a semiconductor wafer to obtain a wafer appearance prediction that is expected to result from a second wafer manufacturing operation based on a first image obtained after a first wafer manufacturing operation, the second wafer manufacturing operation to be performed subsequent to the first wafer manufacturing operation, and compute defect information based on differences between the wafer appearance prediction and a second image of the semiconductor wafer obtained after the second wafer manufacturing operation.

Example 13 includes the non-transitory machine readable storage medium of example 12, wherein the wafer appearance prediction is a first wafer appearance prediction, wherein, to simulate advancement in the manufacturing process, the instructions, when executed, cause the processor circuitry to cause a first adjustment to data associated with the first image based on a third wafer manufacturing operation performed between the first wafer manufacturing operation and the second wafer manufacturing operation, the first adjustment to result in a second wafer appearance prediction, and cause a second adjustment to the second wafer appearance prediction based on the second wafer manufacturing operation, the second adjustment to result in the first wafer appearance prediction.

Example 14 includes the non-transitory machine readable storage medium of example 12, wherein the manufacturing process is a first manufacturing process, the semiconductor wafer is a first semiconductor wafer, the wafer appearance prediction is a first wafer appearance prediction, and the defect information is first defect information, wherein the instructions, when executed, cause the processor circuitry to simulate advancement in a second manufacturing process of a second semiconductor wafer to obtain a second wafer appearance prediction that is expected to result from a third wafer manufacturing operation based on a third image of the second semiconductor wafer obtained after the first wafer manufacturing operation, the third wafer manufacturing operation to be performed subsequent to the first wafer manufacturing operation, wherein the third wafer manufacturing operation is an alternative to the second wafer manufacturing operation, compute second defect information associated with the second semiconductor wafer based on the second wafer appearance prediction and a fourth image of the second semiconductor wafer obtained after the third wafer manufacturing operation, and determine a preference between the second wafer manufacturing operation and the third wafer manufacturing operation based on the first defect information and the second defect information.

Example 15 includes the non-transitory machine readable storage medium of example 12, wherein the instructions, when executed, cause the processor circuitry to utilize a neural network to simulate the advancement in the manufacturing process and obtain the wafer appearance prediction.

Example 16 includes the non-transitory machine readable storage medium of example 15, wherein the instructions, when executed, cause the processor circuitry to train the neural network using first sample wafer images captured after performance of the first wafer manufacturing operation on semiconductor wafers associated with the first sample wafer images, and second sample wafer images captured after performance of the second wafer manufacturing operation on the semiconductor wafers.

Example 17 includes the non-transitory machine readable storage medium of example 12, wherein advancement in the manufacturing process is simulated before completion of the second wafer manufacturing operation on the semiconductor wafer.

Example 18 includes the non-transitory machine readable storage medium of example 12, where, to compute the defect information, the instructions, when executed, cause the processor circuitry to compare the wafer appearance prediction to a corresponding structure in the second image in a same location on the semiconductor wafer as the wafer appearance prediction.

Example 19 includes an apparatus comprising at least one electron-beam tool to capture first information representative of a structure of a semiconductor wafer after a first wafer manufacturing operation, and capture second information representative of the structure of the semiconductor wafer after a second wafer manufacturing operation subsequent to the first wafer manufacturing operation, interface circuitry to access the first information and the second information, and processor circuitry including one or more of at least one of a central processor unit, a graphics processor unit, or a digital signal processor, the at least one of the central processor unit, the graphics processor unit, or the digital signal processor having control circuitry to control data movement within the processor circuitry, arithmetic and logic circuitry to perform one or more first operations corresponding to instructions, and one or more registers to store a result of the one or more first operations, the instructions in the apparatus, a Field Programmable Gate Array (FPGA), the FPGA including logic gate circuitry, a plurality of configurable interconnections, and storage circuitry, the logic gate circuitry and the plurality of the configurable interconnections to perform one or more second operations, the storage circuitry to store a result of the one or more second operations, or Application Specific Integrated Circuitry (ASIC) including logic gate circuitry to perform one or more third operations, the processor circuitry to perform at least one of the first operations, the second operations, or the third operations to instantiate wafer structure prediction circuitry to determine projected wafer information that is to result from the second wafer manufacturing operation based on the first information, and defect detection circuitry to detect whether an actual defect developed between completion of the first wafer manufacturing operation and completion of the second wafer manufacturing operation based on the second information and the projected wafer information.

Example 20 includes the apparatus of example 19, wherein the wafer structure prediction circuitry is to determine the projected wafer information using a generative adversarial network.

Example 21 includes the apparatus of example 19, wherein the wafer structure prediction circuitry is to determine a first change to the structure of the semiconductor wafer based on the first information and a third wafer manufacturing operation performed between the first wafer manufacturing operation and the second wafer manufacturing operation, and determine a second change to the structure of the semiconductor wafer based on the first information, the first change, and the second wafer manufacturing operation.

Example 22 includes the apparatus of example 21, wherein the first change is associated with dimensions of a pattern on the semiconductor wafer, and wherein the second change is associated with a contrast of the pattern on the semiconductor wafer.

Example 23 includes the apparatus of example 19, wherein the semiconductor wafer is a first semiconductor wafer formed of a first material, the structure is a first structure, the projected wafer information is first projected wafer information, and the actual defect is a first actual defect, wherein the at least one electron-beam tool is to capture third information associated with a second structure of a second semiconductor wafer formed of a second material in response to performance of the first wafer manufacturing operation on the second semiconductor wafer, and capture fourth information associated with the second structure of the second semiconductor wafer in response to performance of the second wafer manufacturing operation on the second semiconductor wafer, wherein the wafer structure prediction circuitry is to determine second projected wafer information based on the third information and the second wafer manufacturing operation, and wherein the defect detection circuitry is to detect a second actual defect based on the second projected wafer information and the fourth information.

Example 24 includes the apparatus of example 23, further including evaluation circuitry to rank the first material relative to the second material based on the first defect and the second defect.

Example 25 includes a non-transitory machine readable medium comprising wafer structure prediction instructions to cause at least one machine to predict a structure of a semiconductor wafer that is to result from a second wafer manufacturing operation based on a first image of the semiconductor wafer obtained after a first wafer manufacturing operation, the second wafer manufacturing operation to be performed subsequent to the first wafer manufacturing operation, the predicted structure corresponding to an associated state of the semiconductor wafer, and defect detection instructions to cause the at least one machine to compare the predicted structure of the semiconductor wafer to a second image of the semiconductor wafer obtained after the second wafer manufacturing operation to identify whether an actual defect developed in the semiconductor wafer between completion of the first wafer manufacturing operation and completion of the second wafer manufacturing operation.

Example 26 includes the non-transitory machine readable medium of example 25, wherein the wafer structure prediction instructions cause the at least one machine to input the first image in a generative adversarial network to predict the structure of the semiconductor wafer.

Example 27 includes the non-transitory machine readable medium of example 25, further including defect evaluation instructions to cause the at least one machine to generate an alert when a quantity of the actual defect satisfies a threshold.

Example 28 includes the non-transitory machine readable medium of example 25, wherein the wafer structure prediction instructions cause the at least one machine to transform the first image into a third image representative of the predicted structure based on the second wafer manufacturing operation.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

What is claimed is:

1. An apparatus comprising:
memory;
machine readable instructions; and
processor circuitry to at least one of instantiate operations corresponding to the machine readable instructions or execute the machine readable instructions to:
predict a structure of a semiconductor wafer that is to result from a second wafer manufacturing operation based on a first image of the semiconductor wafer obtained after a first wafer manufacturing operation, the second wafer manufacturing operation to be performed subsequent to the first wafer manufacturing operation; and
determine whether an actual defect developed in the semiconductor wafer between completion of the first wafer manufacturing operation and completion of the second wafer manufacturing operation based on the predicted structure of the semiconductor wafer and a second image representative of the semiconductor wafer after completion of the second wafer manufacturing operation.

2. The apparatus of claim 1, wherein the actual defect includes at least one of a bridge that connects a first word line and a second word line in the semiconductor wafer, a metal tip-to-tip short, a metal side-to-side short, an epitaxy short, or a contact-to-gate short.

3. The apparatus of claim 1, wherein, to predict the structure of the semiconductor wafer, the processor circuitry is to simulate a change in the first image that is to occur during at least the second wafer manufacturing operation using a generative adversarial network.

4. The apparatus of claim 1, wherein, to predict the structure of the semiconductor wafer, the processor circuitry is to transform the first image into a third image representative of the predicted structure based on the second wafer manufacturing operation.

5. The apparatus of claim 1, wherein, to predict the structure of the semiconductor wafer, the processor circuitry is to:
cause a first adjustment to the first image to generate a third image based on a third wafer manufacturing operation performed between the first wafer manufacturing operation and the second wafer manufacturing operation; and
cause a second adjustment to the third image to generate the predicted structure based on the second wafer manufacturing operation.

6. The apparatus of claim 1, wherein the processor circuitry is to obtain the first and second images via an electron-beam microscope.

7. The apparatus of claim 1, wherein the processor circuitry is to generate an alert in response to detection of the actual defect.

8. The apparatus of claim 1, wherein the semiconductor wafer is a first semiconductor wafer, and the actual defect is a first set of actual defects, wherein the processor circuitry is to:
obtain a third image of a second semiconductor wafer after a third wafer manufacturing operation, wherein the third wafer manufacturing operation is in replacement of the second wafer manufacturing operation; and
perform a comparison between the predicted structure and the third image to determine whether a second set of actual defects developed in the second semiconductor wafer between the first wafer manufacturing operation and the third wafer manufacturing operation.

9. The apparatus of claim 8, wherein the first set of actual defects includes a first quantity of defects and the second set of actual defects includes a second quantity of defects, and wherein the second quantity of defects and the first quantity of defects are indicative of an effectiveness of the third wafer manufacturing operation relative to the second wafer manufacturing operation.

10. The apparatus of claim 1, wherein the processor circuitry is to predict the structure of the semiconductor wafer before completion of the second wafer manufacturing operation and after completion of the first wafer manufacturing operation.

11. The apparatus of claim 1, wherein the processor circuitry is to compare the predicted structure to a corresponding structure in the second image, the corresponding structure in a location on the semiconductor wafer where the predicted structure is expected.

12. A non-transitory machine readable storage medium comprising instructions that, when executed, cause processor circuitry to at least:
simulate advancement in a manufacturing process of a semiconductor wafer to obtain a wafer appearance prediction that is expected to result from a second wafer manufacturing operation based on a first image obtained after a first wafer manufacturing operation, the second wafer manufacturing operation to be performed subsequent to the first wafer manufacturing operation; and
compute defect information based on differences between the wafer appearance prediction and a second image of the semiconductor wafer obtained after the second wafer manufacturing operation.

13. The non-transitory machine readable storage medium of claim 12, wherein the wafer appearance prediction is a first wafer appearance prediction, wherein, to simulate advancement in the manufacturing process, the instructions, when executed, cause the processor circuitry to:
cause a first adjustment to data associated with the first image based on a third wafer manufacturing operation performed between the first wafer manufacturing operation and the second wafer manufacturing operation, the first adjustment to result in a second wafer appearance prediction; and
cause a second adjustment to the second wafer appearance prediction based on the second wafer manufacturing operation, the second adjustment to result in the first wafer appearance prediction.

14. The non-transitory machine readable storage medium of claim 12, wherein the manufacturing process is a first manufacturing process, the semiconductor wafer is a first semiconductor wafer, the wafer appearance prediction is a first wafer appearance prediction, and the defect information is first defect information, wherein the instructions, when executed, cause the processor circuitry to:
simulate advancement in a second manufacturing process of a second semiconductor wafer to obtain a second wafer appearance prediction that is expected to result from a third wafer manufacturing operation based on a third image of the second semiconductor wafer obtained after the first wafer manufacturing operation, the third wafer manufacturing operation to be performed subsequent to the first wafer manufacturing operation, wherein the third wafer manufacturing operation is an alternative to the second wafer manufacturing operation;
compute second defect information associated with the second semiconductor wafer based on the second wafer appearance prediction and a fourth image of the second semiconductor wafer obtained after the third wafer manufacturing operation; and
determine a preference between the second wafer manufacturing operation and the third wafer manufacturing operation based on the first defect information and the second defect information.

15. The non-transitory machine readable storage medium of claim 12, wherein the instructions, when executed, cause the processor circuitry to utilize a neural network to simulate the advancement in the manufacturing process and obtain the wafer appearance prediction.

16. The non-transitory machine readable storage medium of claim 15, wherein the instructions, when executed, cause the processor circuitry to train the neural network using first sample wafer images captured after performance of the first wafer manufacturing operation on semiconductor wafers associated with the first sample wafer images, and second sample wafer images captured after performance of the second wafer manufacturing operation on the semiconductor wafers.

17. The non-transitory machine readable storage medium of claim 12, wherein advancement in the manufacturing process is simulated before completion of the second wafer manufacturing operation on the semiconductor wafer.

18. The non-transitory machine readable storage medium of claim 12, where, to compute the defect information, the instructions, when executed, cause the processor circuitry to compare the wafer appearance prediction to a corresponding structure in the second image in a same location on the semiconductor wafer as the wafer appearance prediction.

19. An apparatus comprising:
at least one electron-beam tool to:
capture first information representative of a structure of a semiconductor wafer after a first wafer manufacturing operation; and
capture second information representative of the structure of the semiconductor wafer after a second wafer manufacturing operation subsequent to the first wafer manufacturing operation;
interface circuitry to access the first information and the second information; and
processor circuitry including one or more of:
at least one of a central processor unit, a graphics processor unit, or a digital signal processor, the at least one of the central processor unit, the graphics processor unit, or the digital signal processor having control circuitry to control data movement within the processor circuitry, arithmetic and logic circuitry to perform one or more first operations corresponding to instructions, and one or more registers to store a result of the one or more first operations, the instructions in the apparatus;
a Field Programmable Gate Array (FPGA), the FPGA including logic gate circuitry, a plurality of configurable interconnections, and storage circuitry, the logic gate circuitry and the plurality of the configurable interconnections to perform one or more second operations, the storage circuitry to store a result of the one or more second operations; or
Application Specific Integrated Circuitry (ASIC) including logic gate circuitry to perform one or more third operations;
the processor circuitry to perform at least one of the first operations, the second operations, or the third operations to instantiate:
wafer structure prediction circuitry to determine projected wafer information that is to result from the second wafer manufacturing operation based on the first information; and
defect detection circuitry to detect whether an actual defect developed between completion of the first wafer manufacturing operation and completion of the second wafer manufacturing operation based on the second information and the projected wafer information.

20. The apparatus of claim 19, wherein the wafer structure prediction circuitry is to determine the projected wafer information using a generative adversarial network.

21. The apparatus of claim 19, wherein the wafer structure prediction circuitry is to:
determine a first change to the structure of the semiconductor wafer based on the first information and a third wafer manufacturing operation performed between the first wafer manufacturing operation and the second wafer manufacturing operation; and
determine a second change to the structure of the semiconductor wafer based on the first information, the first change, and the second wafer manufacturing operation.

22. The apparatus of claim 21, wherein the first change is associated with dimensions of a pattern on the semiconductor wafer, and wherein the second change is associated with a contrast of the pattern on the semiconductor wafer.

23. The apparatus of claim 19, wherein the semiconductor wafer is a first semiconductor wafer formed of a first material, the structure is a first structure, the projected wafer information is first projected wafer information, and the actual defect is a first actual defect,
wherein the at least one electron-beam tool is to:
capture third information associated with a second structure of a second semiconductor wafer formed of a second material in response to performance of the first wafer manufacturing operation on the second semiconductor wafer; and
capture fourth information associated with the second structure of the second semiconductor wafer in response to performance of the second wafer manufacturing operation on the second semiconductor wafer;
wherein the wafer structure prediction circuitry is to determine second projected wafer information based on the third information and the second wafer manufacturing operation; and
wherein the defect detection circuitry is to detect a second actual defect based on the second projected wafer information and the fourth information.

24. The apparatus of claim 23, further including evaluation circuitry to rank the first material relative to the second material based on the first defect and the second defect.

25. A non-transitory machine readable medium comprising:
wafer structure prediction instructions to cause at least one machine to predict a structure of a semiconductor wafer that is to result from a second wafer manufacturing operation based on a first image of the semiconductor wafer obtained after a first wafer manufacturing operation, the second wafer manufacturing operation to be performed subsequent to the first wafer manufacturing operation, the predicted structure corresponding to an associated state of the semiconductor wafer; and
defect detection instructions to cause the at least one machine to compare the predicted structure of the semiconductor wafer to a second image of the semiconductor wafer obtained after the second wafer manufacturing operation to identify whether an actual defect developed in the semiconductor wafer between completion of the first wafer manufacturing operation and completion of the second wafer manufacturing operation.

26. The non-transitory machine readable medium of claim 25, wherein the wafer structure prediction instructions cause the at least one machine to input the first image in a generative adversarial network to predict the structure of the semiconductor wafer.

27. The non-transitory machine readable medium of claim 25, further including defect evaluation instructions to cause the at least one machine to generate an alert when a quantity of the actual defect satisfies a threshold.

28. The non-transitory machine readable medium of claim 25, wherein the wafer structure prediction instructions cause the at least one machine to transform the first image into a third image representative of the predicted structure based on the second wafer manufacturing operation.
